(19) United States
(12) Patent Application Publication
(10) Pub. No.: US 2025/0054734 A1
(43) Pub. Date: Feb. 13, 2025

(54) SHOWERHEAD FACEPLATE CONFIGURATIONS

(71) Applicant: LAM RESEARCH CORPORATION, Fremont, CA (US)

(72) Inventors: Bin LUO, Beaverton, OR (US); Stephen TOPPING, Portland, OR (US); Keith Joseph MARTIN, Tualatin, OR (US); Weifeng CHENG, Portland, OR (US); Yogesh BABBAR, Hillsboro, OR (US); Pramod SUBRAMONIUM, Portland, OR (US)

(21) Appl. No.: 18/710,671

(22) PCT Filed: Nov. 17, 2022
(86) PCT No.: PCT/US2022/050241

§ 371 Date: May 16, 2024

Related U.S. Application Data
(60) Provisional application No. 63/283,971, filed on Nov. 29, 2021.

(51) Int. Cl. H01J 37/32; C23C 16/455

(52) U.S. Cl. CPC H01J 37/32449; C23C 16/45565; H01J 37/32715; H01J 37/32082; H01J 2237/202; H01J 2237/332

(57) ABSTRACT

A showerhead for processing a substrate comprises a backplate and a faceplate attached to the backplate. The faceplate comprises a first surface facing the backplate, a second surface opposite to the first surface, and a plurality of through holes extending between the first and second surfaces. At least one of the first and second surfaces is at least partially contoured.

### CROSS-REFERENCE TO RELATED APPLICATIONS

This application claims the benefit of U.S. Provisional Application No. 63/283,971, filed on Nov. 29, 2021. The entire disclosure of the application referenced above is incorporated herein by reference.

### FIELD

The present disclosure relates generally to substrate processing systems and more particularly to faceplate configurations for showerheads used in the substrate processing systems.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems (also called tools) comprise processing chambers (also called stations or process modules). In the processing chambers, semiconductor substrates (also called wafers) are arranged on a pedestal. One or more process gases are supplied from a showerhead to the processing chamber. Plasma is struck between the showerhead and the pedestal to deposit material on or to remove (etch) material from the substrate.

### SUMMARY

A showerhead for processing a substrate comprises a backplate and a faceplate attached to the backplate. The faceplate comprises a first surface facing the backplate, a second surface opposite to the first surface, and a plurality of through holes extending between the first and second surfaces. At least one of the first and second surfaces is at least partially contoured.

In additional features, a contoured portion of the at least one of the first and second surfaces is at least partially concave.

In additional features, a contoured portion of the at least one of the first and second surfaces is at least partially convex.

In additional features, the backplate and the faceplate are cylindrical, and a contoured portion of the at least one of the first and second surfaces slopes from an outer diameter of the faceplate to an inner diameter of the faceplate.

In additional features, the backplate and the faceplate are cylindrical, and a contoured portion of the at least one of the first and second surfaces slopes from an inner diameter of the faceplate to an outer diameter of the faceplate.

In additional features, the backplate and the faceplate are cylindrical. A first contoured portion of one of the first and second surfaces slopes from an inner diameter of the faceplate to an outer diameter of the faceplate. A second contoured portion of the other of the first and second surfaces slopes from the outer diameter of the faceplate to the inner diameter of the faceplate.

In additional features, a contoured portion of the at least one of the first and second surfaces has a linear slope.

In additional features, a contoured portion of the at least a portion of the at least one of the first and second surfaces has a polynomial slope.

In additional features, a contoured portion of the at least a portion of the at least one of the first and second surfaces has a linear slope and a polynomial slope.

In additional features, a contoured portion of the at least one of the first and second surfaces at least partially extends towards the backplate.

In additional features, a contoured portion of the at least one of the first and second surfaces at least partially extends away from the backplate.

In additional features, a first contoured portion of one of the first and second surfaces at least partially extends towards the backplate. A second contoured portion of the other of the first and second surfaces at least partially extends away from the backplate.

In additional features, the through holes lie within a contoured portion of the at least one of the first and second surfaces.

In additional features, a portion of the through holes lies outside a contoured portion of the at least one of the first and second surfaces.

In additional features, the backplate and the faceplate are cylindrical, and a contoured portion of the at least one of the first and second surfaces extends within an inner diameter of the faceplate.

In additional features, the backplate and the faceplate are cylindrical, and a contoured portion of the second surface extends within an outer diameter of the faceplate.

In additional features, the backplate and the faceplate are cylindrical. A contoured portion of the first surface extends within an inner diameter of the faceplate. A contoured portion of the second surface extends within an outer diameter of the faceplate.

In additional features, the backplate and the faceplate are cylindrical. The faceplate comprises a sidewall attached to the backplate. The backplate, the faceplate, and the sidewall define a plenum. The showerhead further comprises a stem portion attached to the backplate. The stem portion comprises a gas inlet. A conduit extends from the gas inlet through the stem portion, the backplate, and the faceplate to the plenum. The gas inlet, the plenum, and the through holes are in fluid communication with each other.

In additional features, a system comprises the showerhead, a pedestal to support the substrate, an actuator to move the pedestal relative to the showerhead, and a controller to control the actuator.

In additional features, a system comprises the showerhead, a gas source to supply a gas to the inlet, a pedestal to support the substrate, a radio frequency source to supply radio frequency power to activate the gas, an actuator to move the pedestal relative to the showerhead. The system comprises a controller to control the gas source, the radio frequency source, and the actuator.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 shows an example of a substrate processing system comprising a processing chamber;

FIG. 2 shows a cross-sectional view of an example of a showerhead;

FIG. 3 shows a cross-sectional view of an example of a showerhead comprising a faceplate with internal contouring (i.e., with contouring on a side of the faceplate that is facing away from a substrate);

FIGS. 4-6 show cross-sectional views of examples of showerheads comprising faceplates with external contouring (i.e., with contouring on a side of the faceplate that is facing the substrate); and

FIGS. 7-10 show cross-sectional views of examples of showerheads comprising faceplates with internal and external contouring (i.e., with contouring on both sides of the faceplate that are facing away from the substrate and facing the substrate).

In the drawings, reference numbers may be reused to identify similar and/or identical elements.

### DETAILED DESCRIPTION

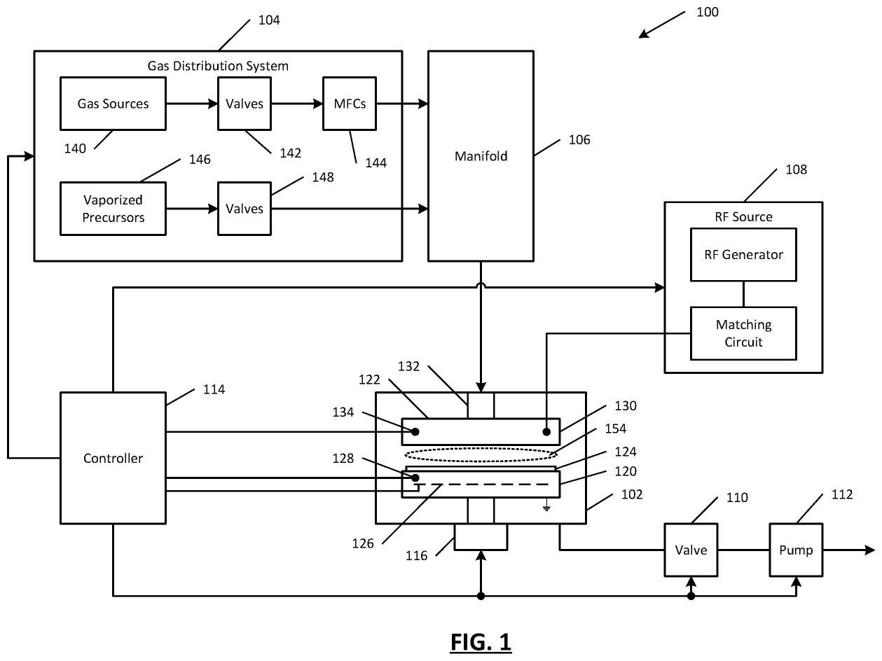

In substrate processing systems (see example shown in FIG. 1), a film may be deposited on a substrate arranged on a pedestal by supplying one or more process gases from a showerhead. Some deposition processes also use plasma during deposition. Many factors affect properties (i.e., a thickness profile) of the film deposited on the substrate. Non-limiting examples of the factors affecting the film properties include the size, density, and distribution of through holes in a faceplate of the showerhead; the shape of the faceplate; and a distance between the faceplate and the substrate.

Some applications require a radially uniform (flat) thickness profile for films deposited on substrates while others require profiles that are not radially uniform but are radially varying. Many techniques are used to vary the film properties. For example, parameters such as flow rate of the process gases through the showerhead, plasma density distribution, and so on can be controlled to tune the film profiles. However, these techniques tend to be inadequate and have undesirable side effects.

The present disclosure provides faceplates of various shapes to tune the properties of the film deposited on the substrate. Specifically, as explained below in detail, the faceplate may be contoured on the inside (i.e., on a side facing away from the substrate), on the outside (i.e., on a side facing the substrate), or a combination thereof. As used herein, contouring a surface means shaping a surface as described in the present disclosure. For example, a contoured surface is a surface having a shape, outline, or a profile as described herein. For example, a contoured surface includes a curved surface, a surface having a slope, or a surface that includes a curved portion, a portion having a slope, a flat surface, or any combination thereof. The contouring of the faceplate changes the height (or depth) of the through holes in the faceplate along the radius of the showerhead. The variations in the depth of the through holes along the radius changes the resistance to the flow of process gases across the radius of the showerhead. The changes in the resistance to the flow of process gases across the radius changes the film profile of the film deposited on the substrate.

In particular, the internal contouring of the faceplate can tune radial profiles of films by radially tuning pressure distribution of the process gases. The external contouring of the faceplate can tune the radial profiles of the films by radially tuning pressure distribution of the process gases and by radially tuning plasma density. For example, in addition to using the internal and/or external contoured faceplates, the distance between the faceplate and the substrate (i.e., a gap between the showerhead and a pedestal) can be adjusted to further tune the film properties. The external contouring of the faceplate can also impact other properties such as stresses on the substrate. These and other features of the present disclosure are described below in detail. SUBSTRATE PROCESSING SYSTEM

FIG. 1 shows an example of a substrate processing system 100. The substrate processing system 100 comprises a processing chamber 102, a gas distribution system 104, a manifold 106, a radio frequency (RF) source 108, a valve 110, a pump 112, and a controller 114.

The processing chamber 102 comprises a pedestal 120 and a showerhead 122 arranged above the pedestal 120. A substrate 124 is arranged on the pedestal 120 during processing.

The pedestal 120 comprises one or more heaters generally shown at 126. While not shown, the pedestal 120 may also comprise cooling channels through which a coolant can be circulated. The pedestal 120 also comprises one or more temperature sensors generally shown at 128. The heaters 126 and the cooling channels control the temperature of the substrate 124 during processing.

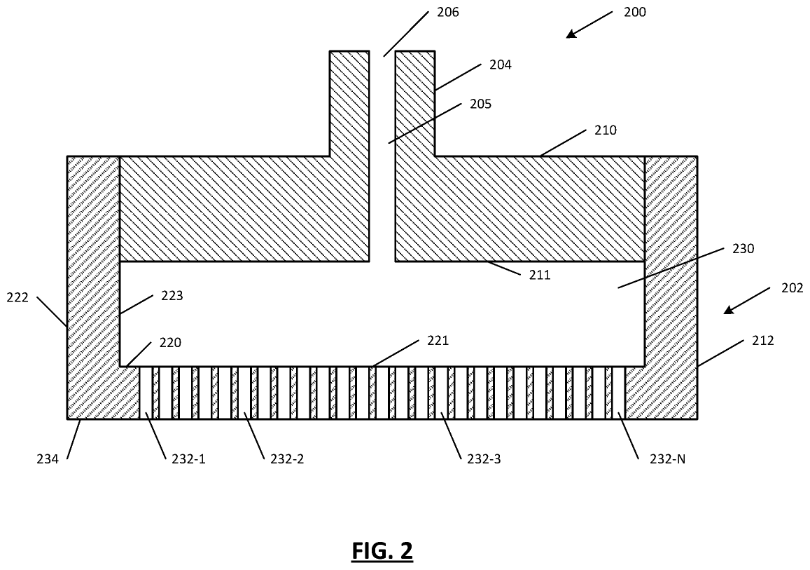

The showerhead 122 comprises a base portion 130 and a stem portion 132. The base portion 130 is generally cylindrical in shape and comprises a backplate and a faceplate, which are shown and described below in detail with reference to FIGS. 2-10. The stem portion 132 extends from a center of the base portion 130 and is attached to a top portion of the processing chamber 102. The showerhead 130 may also comprise a heater and a cooling channel (both not shown). The showerhead 130 also comprises one or more temperature sensors generally shown at 134.

The gas distribution system 104 comprises a plurality of gas sources 140, a plurality of valves 142, a plurality of mass flow controllers (MFCs) 144. The gas sources 140 supply process gases through the valves 142 and MFCs 144 to the manifold 106. The gas distribution system 104 also supplies one or more vaporized precursors 146 through one or more valves 148 to the manifold 106. The manifold 106 supplies one or more process gases and/or one or more vaporized precursors to the showerhead 130 through the stem portion 132 of the showerhead 130. The showerhead 130 supplies the gases into the processing chamber 102 via through holes in the faceplate of the showerhead, which are shown in FIGS. 2-10.

The RF source 108 comprises an RF generator 150 and a matching circuit 152. The RF generator generates RF power. The matching circuit 152 supplies the RF power to the showerhead 130 with the pedestal 120 being grounded. Alternatively, the RF power can be supplied to the pedestal 120, and the showerhead 130 can be grounded. The RF power activates the process gases and/or precursors to generate plasma 154.

An actuator 116 moves the pedestal 120 in upward and downward directions to adjust a gap between the pedestal 120 and the showerhead 130 during processing. Alternatively or additionally, while not shown, one or more actuators can be used to move the showerhead 130 relative to the pedestal 120. The valve 110 and the pump 112 maintain pressure in the processing chamber 102 and exhaust gases from the processing chamber 102. The controller 114 controls all of the elements (i.e., components) of the substrate processing system 100 described above. SHOWERHEAD

FIG. 2 shows a cross-section of a showerhead 200 that can be used in the substrate processing system 100 shown in FIG. 1. The showerhead 200 comprises a base portion 202 and a stem portion 204 that extends from the base portion 202. The stem portion 204 includes an inlet 206 to receive process gases. The base portion 202 comprises a backplate 210 and a faceplate 212. The backplate 210 is generally cylindrical. The faceplate 212 is attached to an outer diameter (OD) of the backplate 210 as explained below in further detail. The stem portion 204 extends from a center of the backplate 210.

The faceplate 212 is generally C-shaped and is also cylindrical. Specifically, the faceplate 212 comprises a cylindrical base portion 220 and a sidewall 222. The sidewall 222 extends from the cylindrical base portion 220. The sidewall 222 extends towards the backplate 210 and is attached to the backplate 210. Specifically, the sidewall 222 is attached to the OD of the backplate 210. A bottom surface 211 of the backplate 210 is perpendicular to an inner surface 223 of the sidewall 222. The bottom surface 211 of the backplate 210 is parallel to a plane in which the cylindrical base portion 220 and the backplate 210 lie.

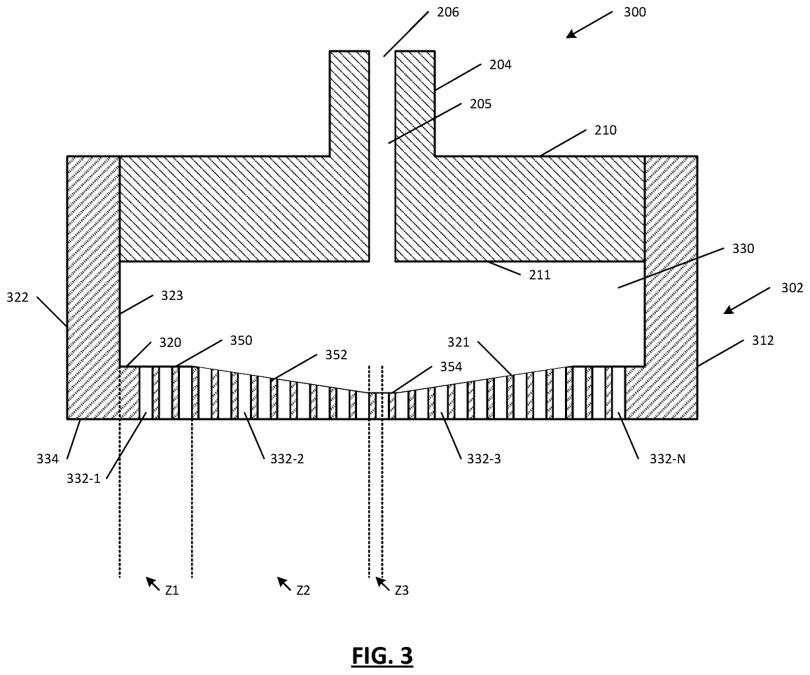

The backplate 210 and the faceplate 212 define a plenum 230. Specifically, the bottom surface 211 of the backplate 210, a top surface 221 of the cylindrical base portion 220, and the inner surface 223 of the sidewall 222 define the plenum 230. A conduit 205 extends from the inlet 206 through the stem portion 204 and backplate 210. The conduit 205 is in fluid communication with the plenum 230. The plenum 230 is in fluid communication with the inlet 206. While not described with reference to FIGS. 3-10, the conduit 205 is shown in FIGS. 3-10 and similarly connects the inlet 206 to the respective plenums shown in FIGS. 3-10.

The cylindrical base portion 220 comprises a plurality of through holes 232-1, 232-2, 232-3, . . . , and 232-N (collectively the through holes 232). The through holes 232 extend from the bottom of the faceplate 212 to the top of the faceplate 212. Specifically, the through holes 232 extend from the bottom of the cylindrical base portion 220 to the top of the cylindrical base portion 220. More specifically, the through holes 232 extend from a bottom surface 234 of the cylindrical base portion 220, which faces a substrate, to the top surface 221 of the cylindrical base portion 220, which faces away from the substrate.

The following description for the top surface 221 and the bottom surface 234 of the cylindrical base portion 220 applies to the top and bottom surfaces of the cylindrical base portions of all of the showerheads shown and described below with reference to FIGS. 3-10. The top surface 221 of the cylindrical base portion 220 faces the bottom surface 211 of the backplate 210 and is parallel to the bottom surface 211 of the backplate 210. Accordingly, the top surface 221 of the cylindrical base portion 220 faces away from the substrate. The top surface 221 may also be called an inner surface 221 of the cylindrical base portion 220, and the bottom surface 234 may also be called an outer surface 234 of the cylindrical base portion 220. In general, the top surface 221 may be called a first surface of the of the cylindrical base portion 220, and the bottom surface 234 may be called a second surface of the cylindrical base portion 220. The alternate terminology for the top and bottom surfaces of the cylindrical base portion and the spatial relationship of the top and bottom surfaces of the cylindrical base portion relative to the backplate 210 and the substrate applies to the top and bottom surfaces of the cylindrical base portions of all of the showerheads described below with reference to FIGS. 3-10.

The through holes 232 extend through the cylindrical base portion 220 vertically along an axis perpendicular to the plane in which the cylindrical base portion 220 and the backplate 210 lie. The through holes 232 are distributed from a center of the cylindrical base portion 220 up to an inner diameter (ID) of the sidewall 222. The through holes 232 are in fluid communication with the plenum 230 and the inlet 206. The gases received from the inlet 206 flow through the plenum 230 and via the through holes 232 into the processing chamber.

The following description of the through holes 232 applies to all of the through holes shown and described below with reference to FIGS. 3-10. While only a few through holes 232 are shown for illustrative convenience, the number of through holes 232 can be on the order of several thousands. In some applications, while not shown, the through holes 232 can be arranged in different patterns. For example, the through holes 232 can be arranged in a square pattern, a hexagonal (honeycomb) pattern and so on. In some applications, the through holes 232 can be arranged in different regions or zones of different shapes distributed across the cylindrical base portion 220. In some applications, the through holes 232 can be of varying diameters, and the density of the through holes 232 can be varied across the zones. In some applications, the through holes 232 may not be vertical. Additionally, the height of the through holes 232 can be varied by contouring the cylindrical base portion 220 as described below with reference to FIGS. 3-10. In some applications, any combination of these arrangements of the through holes 232 can be used.

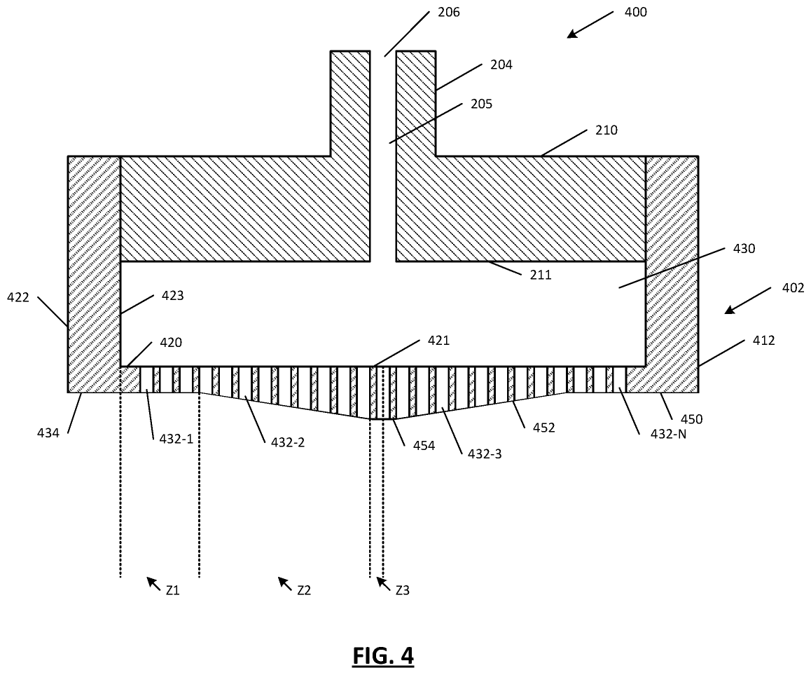

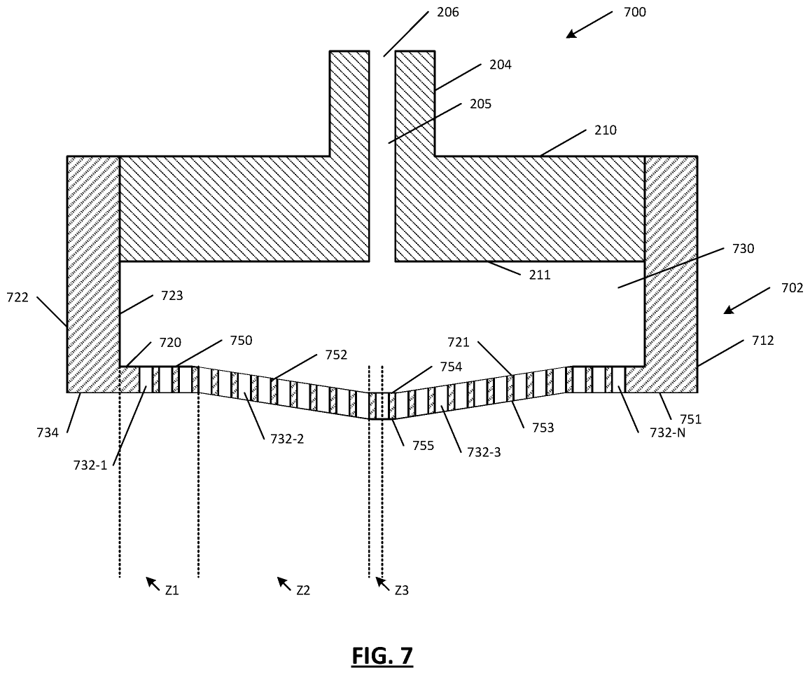

FIGS. 3-10 show showerheads including various configurations of faceplates according to the present disclosure. The showerheads shown in FIGS. 3-10 can be used in the substrate processing system 100 shown in FIG. 1. The faceplates of the showerheads shown in FIGS. 3-10 differ from the faceplate 212 as shown and described below. FIG. 3 shows an example of a faceplate with internal contouring. FIGS. 4-6 show examples of faceplates with external contouring. FIGS. 7-10 show examples of faceplates with internal and external contouring. Note that the shapes of contoured portions of either or both of the top and bottom surfaces of the cylindrical base portions can be varied in many ways depending on process requirements. The contouring shown in FIGS. 3-10 is only illustrative and is nonlimiting.

Faceplate with Internal Contouring

FIG. 3 shows a showerhead 300 comprising a faceplate according to the present disclosure. The faceplate comprises internal contouring as described below in detail. The showerhead 300 comprises a base portion 302 and the stem portion 204. The base portion 302 comprises the backplate 210 and a faceplate 312. The faceplate 312 is generally C-shaped and is also cylindrical. Specifically, the faceplate 312 comprises a cylindrical base portion 320 and a sidewall 322. The sidewall 322 extends from the cylindrical base portion 320. The sidewall 322 extends towards the backplate 210 and is attached to the backplate 210. Specifically, the sidewall 322 is attached to the OD of the backplate 210. The bottom surface 211 of the backplate 210 is perpendicular to an inner surface 323 of the sidewall 322.

The backplate 210 and the faceplate 312 define a plenum 330. Specifically, the bottom surface 211 of the backplate 210, a top surface 321 of the cylindrical base portion 320, and the inner surface 323 of the sidewall 322 define the plenum 330. The plenum 330 is in fluid communication with the inlet 206.

The top surface 321 of the cylindrical base portion 320, which faces away from a substrate, is not flat. Instead, the top surface 321 of the cylindrical base portion 320 is contoured. For example, the top surface 321 of the cylindrical base portion 320 is generally concave. Specifically, a first portion 350 of the top surface 321 extends radially inwardly from the ID of the side wall 322 for a first distance. The first portion 350 extends perpendicularly from the inner surface 323 of the sidewall 322 for the first distance. The first portion 350 extends parallel to a bottom surface 334 of the cylindrical base portion 320 and parallel to the bottom surface 211 of the backplate 210 for the first distance.

Thereafter, a second portion 352 of the top surface 321 extends radially inwards from the first portion 350 and tapers towards the bottom surface 334 of the cylindrical base portion 320 for a second distance. The second portion 352 tapers towards a center of the cylindrical base portion 320 for the second distance. Thereafter, a third portion 354 of the top surface 321 extends from the second portion 352 to the center of the cylindrical base portion 320 for a third distance. The third portion 354 extends parallel to the bottom surface 334 of the cylindrical base portion 320 for the third distance. The bottom surface 334 of the cylindrical base portion 320, which faces the substrate, is perpendicular to the inner surface 323 of the sidewall 322 and is parallel to the bottom surface 211 of the backplate 210. Therefore, the third portion 354 of the top surface 321 also extends perpendicularly to the inner surface 323 of the sidewall 322 for the third distance and is parallel to the bottom surface 211 of the backplate 210.

The generally concave shaping of the top surface 321 described above is also called an internal contouring of the faceplate 312 because the top surface 321 of the cylindrical base portion 320 is also an inner surface of the faceplate 312. Note that the contouring of the top surface 321 may begin at any radial point on the top surface 321 of the cylindrical base portion 320. Similarly, the contouring of the top surface 321 may also end at any radial point on the top surface 321 of the cylindrical base portion 320. For example, the first, second, and third distances can be varied. Further, the slope of the contoured portion of the top surface 321 may be linear or polynomial.

The cylindrical base portion 320 comprises a plurality of through holes 332-1, 332-2, 332-3, . . . , and 332-N (collectively the through holes 332). The through holes 332 extend from the bottom of the faceplate 312 to the top of the faceplate 312. Specifically, the through holes 332 extend from the bottom of the cylindrical base portion 320 to the top of the cylindrical base portion 320. More specifically, the through holes 332 extend from the bottom surface 334 of the cylindrical base portion 320, which faces the substrate, to the top surface 321 of the cylindrical base portion 320, which faces away from the substrate. The bottom surface 334 may also be called an outer surface 334 of the cylindrical base portion 320, and the top surface 321 may also be called an inner surface 321 of the cylindrical base portion 320.

The through holes 332 extend through the cylindrical base portion 320 vertically along an axis perpendicular to a plane in which the cylindrical base portion 320 and the backplate 210 lie. The through holes 332 are distributed from the center of the cylindrical base portion 320 up to the ID of the sidewall 322. The through holes 332 are in fluid communication with the plenum 330 and the inlet 206. The gases received from the inlet 206 flow through the plenum 330 and via the through holes 332 into the processing chamber.

Due to the contouring of the top surface 321 of the cylindrical base portion 320, the height (or depth) of the through holes 332 in the cylindrical base portion 320 varies from the ID of the sidewall 322 to the center of the cylindrical base portion 320 as shown. The varying height of the through holes 332 changes the resistance to the flow of process gases across the radius of the showerhead 300. The changes in the resistance to the flow of process gases across the radius changes the film profile of the film deposited on the substrate. Further, the gap between the showerhead 300 and the substrate can be varied as explained above with reference to FIG. 1. Changing the gap changes the plasma density between the showerhead 300 and the substrate, which further changes the film profile of the film deposited on the substrate.

Specifically, due to the contouring of the top surface 321 of the cylindrical base portion 320, the cylindrical base portion 320 is divided into multiple concentric radial zones. In the example shown, the cylindrical base portion 320 is divided into first, second, and third concentric radial zones shown as Z1, Z2, and Z3, respectively. The first zone Z1 of the cylindrical base portion 320 extends radially inwards from the ID of the sidewall 322 towards the center of the cylindrical base portion 320 for the first distance. An OD of the first zone Z1 is the same as the ID of the sidewall 322. The second zone Z2 of the cylindrical base portion 320 extends radially inwards from an ID of the first zone Z1 towards the center of the cylindrical base portion 320 for the second distance. An OD of the second zone Z2 is the same as the ID of the first zone Z1. The third zone Z3 of the cylindrical base portion 320 extends radially inwards from an ID of the second zone Z2 to the center of the cylindrical base portion 320 for the third distance. An OD of the third zone Z3 is the same as the ID of the second zone Z2.

A width of the first zone Z1 (i.e., a difference between the OD and ID of the first zone Z1) is equal to the first distance. A width of the second zone Z2 (i.e., a difference between the OD and ID of the second zone Z2) is equal to the second distance. A width of the third zone Z3 (i.e., a distance between the OD of the third zone Z3 and the center of the cylindrical base portion 320) is equal to the third distance. The height of the through holes 332 in the first, second, and third radial zones shown as Z1, Z2, and Z3 of the cylindrical base portion 320 varies as follows.

Due to the contouring of the top surface 321 of the cylindrical base portion 320, the outermost through holes 332 in the first zone Z1 that are proximate to the ID of the sidewall 322 have a greater height than the through holes 332 in the second and third zones Z2 and Z3. The innermost through holes 332 in the third zone Z3 that are proximate to the center of the cylindrical base portion 320 have a lesser height than the through holes 332 in the first and second zones Z1 and Z2. Accordingly, the innermost through holes 332 in the third zone Z3 of the cylindrical base portion 320 offer the lowest resistance to the flow of process gases, and the outermost through holes 332 in the first zone Z1 of the cylindrical base portion 320 offer the greatest resistance to the flow of process gases. The height of the through holes 332 in the second zone Z2 is greater than the height of the through holes 332 in the third zone Z3 and is less than the height of the through holes 332 in the first zone Z1. Accordingly, the through holes 332 in second zone Z2 offer greater resistance to the flow of process gases than the through holes 332 in the third zone Z3 and offer lesser resistance to the flow of process gases than the through holes 332 in the first zone Z1.

Specifically, the through holes 332 in the second zone Z2 offer varying resistance to the flow of process gases since the height of the through holes 332 in the second zone Z2 varies throughout the contoured portion in the second zone Z2. More specifically, the height of the through holes 332 in the second zone Z2 gradually decreases from the OD of the second zone Z2 towards the center of the cylindrical base portion 320 (i.e., towards the ID of the second zone Z2). Therefore, the through holes 332 in the second zone Z2 offer a gradually decreasing resistance to the flow of process gases from the OD of the second zone Z2 towards the center of the cylindrical base portion 320 (i.e., towards the ID of the second zone Z2). The outermost through holes 332 in the first zone Z1 offer the greatest resistance to the flow of process gases. Accordingly, the film profile of a substate processed using the showerhead 300 is different than the film profile of a substate processed using the showerhead 200.

Further, the gap between the showerhead 300 and the substrate can be varied as explained above with reference to FIG. 1. Changing the gap changes the plasma density the showerhead 400 and the substrate, which further changes the film profile of the film deposited on the substrate. Accordingly, the film profile of a substate processed using the showerhead 300 is different than the film profiles of substates processed using the showerhead 200.

Faceplates with External Contouring

FIG. 4 shows a showerhead 400 comprising a faceplate according to the present disclosure. The faceplate comprises external contouring as described below in detail. The showerhead 400 comprises a base portion 402 and the stem portion 204. The base portion 402 comprises the backplate 210 and a faceplate 412. The faceplate 412 is generally C-shaped and is also cylindrical. Specifically, the faceplate 412 comprises a cylindrical base portion 420 and a sidewall 422. The sidewall 422 extends from the cylindrical base portion 420. The sidewall 422 extends towards the backplate 210 and is attached to the backplate 210. Specifically, the sidewall 422 is attached to the OD of the backplate 210. The bottom surface 211 of the backplate 210 is perpendicular to an inner surface 423 of the sidewall 422.

The backplate 210 and the faceplate 412 define a plenum 430. Specifically, the bottom surface 211 of the backplate 210, a top surface 421 of the cylindrical base portion 420, and the inner surface 423 of the sidewall 422 define the plenum 430. The plenum 430 is in fluid communication with the inlet 206.

The top surface 421 of the cylindrical base portion 420, which faces away from a substrate, is flat. The top surface 421 of the cylindrical base portion 420 is perpendicular to the inner surface 423 of the sidewall 422. The top surface 421 of the cylindrical base portion 420 is parallel to the bottom surface 211 of the backplate 210. A bottom surface 434 of the cylindrical base portion 420 is not flat. Instead, the bottom surface 434 of the cylindrical base portion 420 is contoured.

Specifically, a first portion 450 of the bottom surface 434 extends radially inwardly from the OD of the side wall 422 for a first distance. The first portion 450 extends perpendicularly from the side wall 422 for the first distance. The first portion 450 extends parallel to the to the top surface 421 of the cylindrical base portion 420 and parallel to the bottom surface 211 of the backplate 210 for the first distance.

Thereafter, a second portion 452 of the bottom surface 434 extends radially inwardly from the first portion 450 for a second distance. The second portion 452 tapers away relative to the top surface 421 towards a center of the cylindrical base portion 420 for the second distance. Thereafter, a third portion 454 of the bottom surface 434 extends from the second portion 452 to the center of the cylindrical base portion 420 for a third distance. The third portion 454 extends parallel to the top surface 421 of the cylindrical base portion 420 for the third distance. The top surface 421 of the cylindrical base portion 420, which faces away from the substrate, is perpendicular to the inner surface 423 of the sidewall 422 and is parallel to the bottom surface 211 of the backplate 210. Therefore, the third portion 454 of the bottom surface 434 also extends perpendicularly to the inner surface 423 of the sidewall 422 for the third distance and is parallel to the bottom surface 211 of the backplate 210.

The generally convex shaping of the bottom surface 434 described above is also called an external contouring of the faceplate 412 because the bottom surface 434 of the cylindrical base portion 420 is also an outer surface of the faceplate 412. Note that the contouring of the bottom surface 434 may begin at any radial point on the bottom surface 434 of the cylindrical base portion 420. Similarly, the contouring of the bottom surface 434 may also end at any radial point on the bottom surface 434 of the cylindrical base portion 420. For example, the first, second, and third distances can be varied. Further, the slope of the contoured portion of the bottom surface 434 may be linear or polynomial.

The cylindrical base portion 420 comprises a plurality of through holes 432-1, 432-2, 432-3, . . . , and 432-N (collectively the through holes 432). The through holes 432 extend from the bottom of the faceplate 412 to the top of the faceplate 412. Specifically, the through holes 432 extend from the bottom of the cylindrical base portion 420 to the top of the cylindrical base portion 420. More specifically, the through holes 432 extend from the bottom surface 434 of the cylindrical base portion 420, which faces the substrate, to the top surface 421 of the cylindrical base portion 420, which faces away from the substrate. The bottom surface 434 may also be called an outer surface 434 of the cylindrical base portion 420, and the top surface 421 may also be called an inner surface 421 of the cylindrical base portion 420.

The through holes 432 extend through the cylindrical base portion 420 vertically along an axis perpendicular to a plane in which the cylindrical base portion 420 and the backplate 210 lie. The through holes 432 are distributed from the center of the cylindrical base portion 420 up to the ID of the sidewall 422. The through holes 432 are in fluid communication with the plenum 430 and the inlet 206. The gases received from the inlet 206 flow through the plenum 430 and via the through holes 432 into the processing chamber.

Due to the contouring of the bottom surface 434 of the cylindrical base portion 420, the height (or depth) of the through holes 432 in the cylindrical base portion 420 varies from the ID of the sidewall 422 to the center of the cylindrical base portion 420 as shown. The varying height of the through holes 432 changes the resistance to the flow of process gases across the radius of the showerhead 400. The changes in the resistance to the flow of process gases across the radius changes the film profile of the film deposited on the substrate.

Additionally, due to the contouring of the bottom surface 434 of the cylindrical base portion 420, the direction in which the process gases exit the through holes 432 also varies, which further changes the film profile of the film deposited on the substrate. Further, the gap between the showerhead 400 and the substrate can be varied as explained above with reference to FIG. 1. Changing the gap changes the plasma density the showerhead 400 and the substrate, which further changes the film profile of the film deposited on the substrate.

Specifically, due to the contouring of the bottom surface 434 of the cylindrical base portion 420, the cylindrical base portion 420 is divided into multiple concentric radial zones. In the example shown, the cylindrical base portion 420 is divided into first, second, and third concentric radial zones shown as Z1, Z2, and Z3, respectively. The first zone Z1 of the cylindrical base portion 420 extends radially inwards from the OD of the sidewall 422 towards the center of the cylindrical base portion 420 for the first distance. An OD of the first zone Z1 is the same as the ID of the sidewall 422. The second zone Z2 of the cylindrical base portion 420 extends radially inwards from an ID of the first zone Z1 towards the center of the cylindrical base portion 420 for the second distance. An OD of the second zone Z2 is the same as the ID of the first zone Z1. The third zone Z3 of the cylindrical base portion 420 extends radially inwards from an ID of the second zone Z2 to the center of the cylindrical base portion 420 for the third distance. An OD of the third zone Z3 is the same as the ID of the second zone Z2.

A width of the first zone Z1 (i.e., a difference between the OD and ID of the first zone Z1) is equal to the first distance. A width of the second zone Z2 (i.e., a difference between the OD and ID of the second zone Z2) is equal to the second distance. A width of the third zone Z3 (i.e., a distance between the OD of the third zone Z3 and the center of the cylindrical base portion 420) is equal to the third distance. The height of the through holes 432 in the first, second, and third radial zones shown as Z1, Z2, and Z3 of the cylindrical base portion 420 varies as follows.

Due to the contouring of the bottom surface 434 of the cylindrical base portion 420, the outermost through holes 432 in the first zone Z1 that are proximate to the ID of the sidewall 422 have a lesser height than the through holes 432 in the second and third zones Z2 and Z3. The innermost through holes 432 in the third zone Z3 that are proximate to the center of the cylindrical base portion 420 have a greater height than the through holes 432 in the first and second zones Z1 and Z2. Accordingly, the outermost through holes 432 in the first zone Z1 offer the lowest resistance to the flow of process gases, and the innermost through holes 432 in the third zone Z3 offer the greatest resistance to the flow of process gases. The height of the through holes 432 in the second zone Z2 is greater than the height of the through holes 432 in the first zone Z1 and is less than the height of the through holes 432 in the third zone Z3. Accordingly, the through holes 432 in second zone Z2 offer greater resistance to the flow of process gases than the through holes 432 in the first zone Z1 and offer lesser resistance to the flow of process gases than the through holes 432 in the third zone Z3.

Specifically, the through holes 432 in the second zone Z2 offer varying resistance to the flow of process gases since the height of the through holes 432 in the second zone Z2 varies throughout the contoured portion in the second zone Z2. More specifically, the height of the through holes 432 in the second zone Z2 gradually increases from the OD of the second zone Z2 towards the center of the cylindrical base portion 420 (i.e., towards the ID of the second zone Z2). Therefore, the through holes 432 in the second zone Z2 offer a gradually increasing resistance to the flow of process gases from the OD of the second zone Z2 towards the center of the cylindrical base portion 420 (i.e., towards the ID of the second zone Z2). The innermost through holes 432 in the third zone Z3 offer the greatest resistance to the flow of process gases.

Further, due to the contouring, the process gases exit via the through holes 432 in the second zone Z2 in a different direction compared to the through holes 432 in the first and third zones Z1 and Z3. Furthermore, the distances between the through holes 432 in the different zones and the substrate are also different. Accordingly, the film profile of a substate processed using the showerhead 400 is different than the film profiles of substates processed using the showerheads 200 and 300.

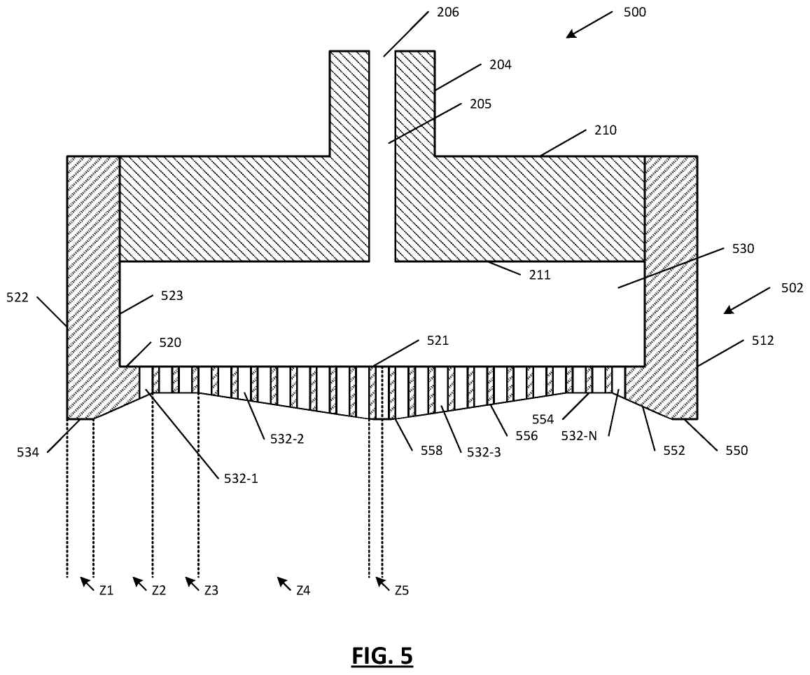

FIG. 5 shows a showerhead 500 comprising a faceplate according to the present disclosure. The faceplate comprises external contouring as described below in detail. The showerhead 500 comprises a base portion 502 and the stem portion 204. The base portion 502 comprises the backplate 210 and a faceplate 512. The faceplate 512 is generally C-shaped and is also cylindrical. Specifically, the faceplate 512 comprises a cylindrical base portion 520 and a sidewall 522. The sidewall 522 extends from the cylindrical base portion 520. The sidewall 522 extends towards the backplate 210 and is attached to the backplate 210. Specifically, the sidewall 522 is attached to the OD of the backplate 210. The bottom surface 211 of the backplate 210 is perpendicular to an inner surface 523 of the sidewall 522.

The backplate 210 and the faceplate 512 define a plenum 530. Specifically, the bottom surface 211 of the backplate 210, a top surface 521 of the cylindrical base portion 520, and the inner surface 523 of the sidewall 522 define the plenum 530. The plenum 530 is in fluid communication with the inlet 206.

The top surface 521 of the cylindrical base portion 520, which faces away from a substrate, is flat. The top surface 521 of the cylindrical base portion 520 is perpendicular to the inner surface 523 of the sidewall 522. The top surface 521 of the cylindrical base portion 520 is parallel to the bottom surface 211 of the backplate 210. A bottom surface 534 of the cylindrical base portion 520 is not flat. Instead, the bottom surface 534 of the cylindrical base portion 520 is contoured.

Specifically, a first portion 550 of the bottom surface 534 extends radially inwardly from the OD of the side wall 522 for a first distance. The first portion 550 extends perpendicularly from the side wall 522 for the first distance and is parallel to the bottom surface 211 of the backplate 210. Thereafter, a second portion 552 of the bottom surface 534 extends from the first portion 550 for a second distance. The second portion 552 tapers radially inwardly towards the top surface 521 for the second distance. The second portion 552 tapers towards a center of the cylindrical base portion 520 for the second distance.

Thereafter, a third portion 554 of the bottom surface 534 extends from the second portion 552 for a third distance. The third portion 554 extends radially inwardly towards the center of the cylindrical base portion 520 for the third distance. The third portion 554 extends perpendicularly to the side wall 522 for the third distance and is parallel to the bottom surface 211 of the backplate 210. The third portion 554 is parallel to the first portion 550.

Thereafter, a fourth portion 556 of the bottom surface 534 extends from the third portion 554 for a fourth distance. The fourth portion 556 tapers away relative to the top surface 521 towards the center of the cylindrical base portion 520 for a fourth distance. Thereafter, a fifth portion 558 of the bottom surface 534 extends from the fourth portion 556 for a fifth distance. The fifth portion 558 extends from the fourth portion 556 to the center of the cylindrical base portion 520 for the fifth distance. The fifth portion 558 extends parallel to the top surface 521 of the cylindrical base portion 520 for the fifth distance and is parallel to the bottom surface 211 of the backplate 210. The top surface 521 of the cylindrical base portion 520, which faces away from the substrate, is perpendicular to the inner surface 523 of the sidewall 522 and is parallel to the bottom surface 211 of the backplate 210. Therefore, the fifth portion 558 of the bottom surface 534 also extends perpendicularly to the inner surface 523 of the sidewall 522 for the fifth distance and is parallel to the bottom surface 211 of the backplate 210. The fifth portion 558 is parallel to the third portion 554 and the first portion 550.

The generally convex shaping of the bottom surface 534 described above is also called an external contouring of the faceplate 512 because the bottom surface 534 of the cylindrical base portion 520 is also an outer surface of the faceplate 512. Note that the contouring of the bottom surface 534 may begin at any radial point on the bottom surface 534 of the cylindrical base portion 520. Similarly, the contouring of the bottom surface 534 may also end at any radial point on the bottom surface 534 of the cylindrical base portion 520. For example, the first, second, third, fourth, and fifth distances can be varied. Further, the slope of the contoured portion of the bottom surface 534 may be linear or polynomial.

The cylindrical base portion 520 comprises a plurality of through holes 532-1, 532-2, 532-3, . . . , and 532-N (collectively the through holes 532). The through holes 532 extend from the bottom of the faceplate 512 to the top of the faceplate 512. Specifically, the through holes 532 extend from the bottom of the cylindrical base portion 520 to the top of the cylindrical base portion 520. More specifically, the through holes 532 extend from the bottom surface 534 of the cylindrical base portion 520, which faces the substrate, to the top surface 521 of the cylindrical base portion 520, which faces away from the substrate. The bottom surface 534 may also be called an outer surface 534 of the cylindrical base portion 520, and the top surface 521 may also be called an inner surface 521 of the cylindrical base portion 520.

The through holes 532 extend through the cylindrical base portion 520 vertically along an axis perpendicular to a plane in which the cylindrical base portion 520 and the backplate 210 lie. The through holes 532 are distributed from the center of the cylindrical base portion 520 up to the ID of the sidewall 522. The through holes 532 are in fluid communication with the plenum 530 and the inlet 206. The gases received from the inlet 206 flow through the plenum 530 and via the through holes 532 into the processing chamber.

Due to the contouring of the bottom surface 534 of the cylindrical base portion 520, the height (or depth) of the through holes 532 in the cylindrical base portion 520 varies from the ID of the sidewall 522 to the center of the cylindrical base portion 520 as shown. The varying height of the through holes 532 changes the resistance to the flow of process gases across the radius of the showerhead 500. The changes in the resistance to the flow of process gases across the radius changes the film profile of the film deposited on the substrate.

Additionally, due to the contouring of the bottom surface 534 of the cylindrical base portion 520, the direction in which the process gases exit the through holes 532 also varies, which further changes the film profile of the film deposited on the substrate. Further, the gap between the showerhead 500 and the substrate can be varied as explained above with reference to FIG. 1. Changing the gap changes the plasma density the showerhead 500 and the substrate, which further changes the film profile of the film deposited on the substrate.

Specifically, due to the contouring of the bottom surface 534 of the cylindrical base portion 520, the cylindrical base portion 520 is divided into multiple concentric radial zones. In the example shown, the cylindrical base portion 520 is divided into first, second, third, fourth, and fifth concentric radial zones shown as Z1, Z2, Z3, Z4, and Z5, respectively. The first zone Z1 of the cylindrical base portion 520 extends radially inwards from the OD of the sidewall 522 towards the center of the cylindrical base portion 520 for the first distance. An OD of the first zone Z1 is the same as the OD of the sidewall 522. In the example shown, the first zone Z1 does not include any of the through holes 532.

The second zone Z2 of the cylindrical base portion 520 extends radially inwards from an ID of the first zone Z1 towards the center of the cylindrical base portion 520 for the second distance. An OD of the second zone Z2 is the same as the ID of the first zone Z1. The third zone Z3 of the cylindrical base portion 520 extends radially inwards from an ID of the second zone Z2 towards the center of the cylindrical base portion 520 for the third distance. An OD of the third zone Z3 is the same as the ID of the second zone Z2.

The fourth zone Z4 of the cylindrical base portion 520 extends radially inwards from an ID of the third zone Z3 towards the center of the cylindrical base portion 520 for the fourth distance. An OD of the fourth zone Z4 is the same as the ID of the third zone Z3. The fifth zone Z5 of the cylindrical base portion 520 extends radially inwards from an ID of the fourth zone Z4 to the center of the cylindrical base portion 520 for the fifth distance. An OD of the fifth zone Z5 is the same as the ID of the fourth zone Z4.

A width of the first zone Z1 (i.e., a difference between the OD and ID of the first zone Z1) is equal to the first distance. A width of the second zone Z2 (i.e., a difference between the OD and ID of the second zone Z2) is equal to the second distance. A width of the third zone Z3 (i.e., a difference between the OD and ID of the third zone Z3) is equal to the third distance. A width of the fourth zone Z4 (i.e., a difference between the OD and ID of the fourth zone Z4) is equal to the fourth distance. A width of the fifth zone Z5 (i.e., a distance between the OD of the fifth zone Z5 and the center of the cylindrical base portion 520) is equal to the fifth distance. The height of the through holes 532 in the first, second, and third radial zones shown as Z1, Z2, and

Z3 of the cylindrical base portion 520 varies as follows.

Due to the contouring of the bottom surface 534 of the cylindrical base portion 520, the outermost through holes 532 in the second zone Z2 have varying height and therefore offer varying resistance to the flow of process gases. Specifically, the height of the through holes 532 in the second zone Z2 gradually decreases from the OD of the second zone Z2 to the ID of the second zone Z2 (i.e., towards the center of the cylindrical base portion 520). Therefore, the through holes 532 in the second zone Z2 offer a gradually decreasing resistance to the flow of process gases from the OD of the second zone Z2 to the ID of the second zone Z2 (i.e., towards the center of the cylindrical base portion 520).

The through holes 532 in the third zone Z3 have a lesser height than the through holes 532 in the second, fourth, and fifth zones Z2, Z4, Z5. Therefore, the through holes 532 in the third zone Z3 offer a lesser resistance to the flow of process gases than the through holes 532 in the second, fourth, and fifth zones Z2, Z4, Z5. In the example shown, the through holes 532 in the third zone Z3 have the smallest height compared to the through holes 532 in the second, fourth, and fifth zones Z2, Z4, Z5. Therefore, the through holes 532 in the third zone Z3 offer the lowest resistance to the flow of process gases compared to the through holes 532 in the second, fourth, and fifth zones Z2, Z4, Z5.

The through holes 532 in the fourth zone Z4 have varying height and therefore offer varying resistance to the flow of process gases. Specifically, the height of the through holes 532 in the fourth zone Z4 gradually increases from the OD of the fourth zone Z4 to the ID of the fourth zone Z4 (i.e., towards the center of the cylindrical base portion 520). Therefore, the through holes 532 in the fourth zone Z4 offer a gradually increasing resistance to the flow of process gases from the OD of the fourth zone Z4 to the ID of the fourth zone Z4 (i.e., towards the center of the cylindrical base portion 520). The height of the through holes 532 in the fourth zone Z4 is greater than the through holes 532 in the third zone Z3 and less than the through holes 532 in the fifth zone Z5. Therefore, the through holes 532 in the fourth zone Z4 offer more resistance to the flow of process gases than the through holes 532 in the third zone Z3 and offer less resistance to the flow of process gases than the through holes 532 in the fifth zone Z5.

The innermost through holes 532 in the fifth zone Z5 have the greatest height and therefore offer the greatest resistance to the flow of process gases. Further, due to the contouring, the process gases exit through holes 532 in the second and fourth zones Z2 and Z4 in different directions compared to the through holes 532 in the third and fifth zones Z3 and Z5. Furthermore, the distances between the through holes 532 in the different zones and the substrate are also different. Accordingly, the film profile of a substate processed using the showerhead 500 is different than the film profiles of substates processed using the showerheads 200, 300, and 400.

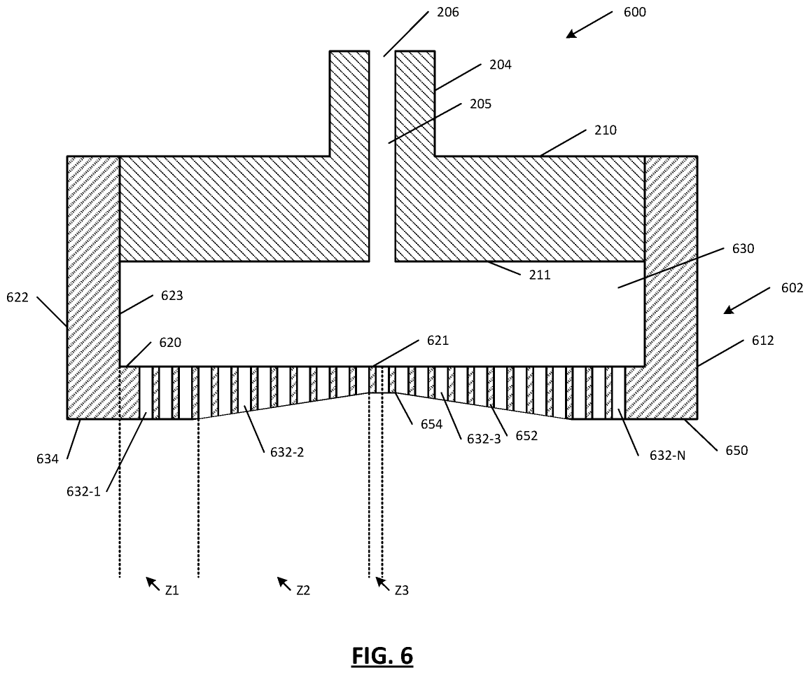

FIG. 6 shows a showerhead 600 comprising a faceplate according to the present disclosure. The faceplate comprises external contouring as described below in detail. The showerhead 600 comprises a base portion 602 and the stem portion 204. The base portion 602 comprises the backplate 210 and a faceplate 612. The faceplate 612 is generally C-shaped and is also cylindrical. Specifically, the faceplate 612 comprises a cylindrical base portion 620 and a sidewall 622. The sidewall 622 extends from the cylindrical base portion 620. The sidewall 622 extends towards the backplate 210 and is attached to the backplate 210. Specifically, the sidewall 622 is attached to the OD of the backplate 210. The bottom surface 211 of the backplate 210 is perpendicular to an inner surface 623 of the sidewall 622.

The backplate 210 and the faceplate 612 define a plenum 630. Specifically, the bottom surface 211 of the backplate 210, a top surface 621 of the cylindrical base portion 620, and the inner surface 623 of the sidewall 622 define the plenum 630. The plenum 630 is in fluid communication with the inlet 206.

The top surface 621 of the cylindrical base portion 620, which faces away from a substrate, is flat. The top surface 621 of the cylindrical base portion 620 is perpendicular to the inner surface 623 of the sidewall 622. The top surface 621 of the cylindrical base portion 620 is parallel to the bottom surface 211 of the backplate 210. A bottom surface 634 of the cylindrical base portion 620 is not flat. Instead, the bottom surface 634 of the cylindrical base portion 620 is contoured.

Specifically, a first portion 650 of the bottom surface 634 extends radially inwardly from the OD of the side wall 622 for a first distance. The first portion 650 extends perpendicularly from the side wall 622 for the first distance. The first portion 650 extends parallel to the top surface 621 of the cylindrical base portion 620 and parallel to the bottom surface 211 of the backplate 210 for the first distance.

Thereafter, a second portion 652 of the bottom surface 634 extends radially inwardly from the first portion 650 for a second distance. The second portion 652 tapers towards the top surface 621 of the cylindrical base portion 620 for the second distance. The second portion 652 tapers towards a center of the cylindrical base portion 620 for the second distance.

Thereafter, a third portion 654 of the bottom surface 434 extends from the second portion 652 to the center of the cylindrical base portion 620 for a third distance. The third portion 654 extends parallel to the top surface 621 of the cylindrical base portion 620 for the third distance. The top surface 621 of the cylindrical base portion 620, which faces away from the substrate, is perpendicular to the inner surface 623 of the sidewall 622 and is parallel to the bottom surface 211 of the backplate 210. Therefore, the third portion 654 of the bottom surface 634 also extends perpendicularly to the inner surface 623 of the sidewall 622 for the third distance and is parallel to the bottom surface 211 of the backplate 210.

The generally concave shaping of the bottom surface 634 described above is also called an external contouring of the faceplate 612 because the bottom surface 634 of the cylindrical base portion 620 is also an outer surface of the faceplate 612. Note that the contouring of the bottom surface 634 may begin at any radial point on the bottom surface 634 of the cylindrical base portion 620. Similarly, the contouring of the bottom surface 634 may also end at any radial point on the bottom surface 634 of the cylindrical base portion 620. For example, the first, second, and third distances can be varied. Further, the slope of the contoured portion of the bottom surface 634 may be linear or polynomial.

The cylindrical base portion 620 comprises a plurality of through holes 632-1, 632-2, 632-3, . . . , and 632-N (collectively the through holes 632). The through holes 632 extend from the bottom of the faceplate 612 to the top of the faceplate 612. Specifically, the through holes 632 extend from the bottom of the cylindrical base portion 620 to the top of the cylindrical base portion 620. More specifically, the through holes 632 extend from the bottom surface 634 of the cylindrical base portion 620, which faces the substrate, to the top surface 621 of the cylindrical base portion 620, which faces away from the substrate. The bottom surface 634 may also be called an outer surface 634 of the cylindrical base portion 620, and the top surface 621 may also be called an inner surface 621 of the cylindrical base portion 620.

The through holes 632 extend through the cylindrical base portion 620 vertically along an axis perpendicular to a plane in which the cylindrical base portion 620 and the backplate 210 lie. The through holes 632 are distributed from the center of the cylindrical base portion 620 up to the ID of the sidewall 622. The through holes 632 are in fluid communication with the plenum 630 and the inlet 206. The gases received from the inlet 206 flow through the plenum 630 and via the through holes 632 into the processing chamber.

Due to the contouring of the bottom surface 634 of the cylindrical base portion 620, the height (or depth) of the through holes 632 in the cylindrical base portion 620 varies from the ID of the sidewall 622 to the center of the cylindrical base portion 620 as shown. The varying height of the through holes 632 changes the resistance to the flow of process gases across the radius of the showerhead 600. The changes in the resistance to the flow of process gases across the radius changes the film profile of the film deposited on the substrate.

Additionally, due to the contouring of the bottom surface 634 of the cylindrical base portion 620, the direction in which the process gases exit the through holes 632 also varies, which further changes the film profile of the film deposited on the substrate. Further, the gap between the showerhead 600 and the substrate can be varied as explained above with reference to FIG. 1. Changing the gap changes the plasma density the showerhead 600 and the substrate, which further changes the film profile of the film deposited on the substrate.

Specifically, due to the contouring of the bottom surface 634 of the cylindrical base portion 620, the cylindrical base portion 620 is divided into multiple concentric radial zones. In the example shown, the cylindrical base portion 620 is divided into first, second, and third concentric radial zones shown as Z1, Z2, and Z3, respectively. The first zone Z1 of the cylindrical base portion 620 extends radially inwards from the OD of the sidewall 622 towards the center of the cylindrical base portion 620 for the first distance. An OD of the first zone Z1 is the same as the ID of the sidewall 622. The second zone Z2 of the cylindrical base portion 620 extends radially inwards from an ID of the first zone Z1 towards the center of the cylindrical base portion 620 for the second distance. An OD of the second zone Z2 is the same as the ID of the first zone Z1. The third zone Z3 of the cylindrical base portion 620 extends radially inwards from an ID of the second zone Z2 to the center of the cylindrical base portion 620 for the third distance. An OD of the third zone Z3 is the same as the ID of the second zone Z2.

A width of the first zone Z1 (i.e., a difference between the OD and ID of the first zone Z1) is equal to the first distance. A width of the second zone Z2 (i.e., a difference between the OD and ID of the second zone Z2) is equal to the second distance. A width of the third zone Z3 (i.e., a distance between the OD of the third zone Z3 and the center of the cylindrical base portion 620) is equal to the third distance. The height of the through holes 632 in the first, second, and third radial zones shown as Z1, Z2, and Z3 of the cylindrical base portion 620 varies as follows.

Due to the contouring of the bottom surface 634 of the cylindrical base portion 620, the outermost through holes 632 in the first zone Z1 that are proximate to the ID of the sidewall 622 have a greater height than the through holes 632 in the second and third zones Z2 and Z3. The innermost through holes 632 in the third zone Z3 that are proximate to the center of the cylindrical base portion 620 have a lesser height than the through holes 632 in the first and second zones Z1 and Z2. Accordingly, the outermost through holes 632 in the first zone Z1 offer the greatest resistance to the flow of process gases, and the innermost through holes 632 in the third zone Z2 offer the lowest resistance to the flow of process gases. The height of the through holes 632 in the second zone Z2 is less than the height of the through holes 632 in the first zone Z1 and is greater than the height of the through holes 632 in the third zone Z3. Accordingly, the through holes 632 in second zone Z2 offer lesser resistance to the flow of process gases than the through holes 632 in the first zone Z1 and offer greater resistance to the flow of process gases than the through holes 632 in the third zone Z3.

Specifically, the through holes 632 in the second zone Z2 offer varying resistance to the flow of process gases since the height of the through holes 632 in the second zone Z2 varies throughout the contoured portion in the second zone Z2. Specifically, the height of the through holes 632 in the second zone Z2 gradually decreases from the OD of the second zone Z2 towards the center of the cylindrical base portion 620 (i.e., towards the ID of the second zone Z2). Therefore, the through holes 632 in the second zone Z2 offer a gradually decreasing resistance to the flow of process gases from the OD of the second zone Z2 towards the center of the cylindrical base portion 620 (i.e., towards the ID of the second zone Z2). The innermost through holes 632 in the third zone Z3 offer the lowest resistance to the flow of process gases.

Further, due to the contouring, the process gases exit through holes 632 in the second zone Z2 in a different direction compared to the through holes 632 in the first and third zones Z1 and Z3. Furthermore, the distances between the through holes 632 in the different zones and the substrate are also different. Accordingly, the film profile of a substate processed using the showerhead 600 is different than the film profiles of substates processed using the showerheads shown in FIGS. 2-5.

Faceplates with Internal and External Contouring

FIG. 7 shows a showerhead 700 comprising a faceplate according to the present disclosure. The faceplate comprises both internal and external contouring as described below in detail. The showerhead 700 comprises a base portion 702 and the stem portion 204. The base portion 702 comprises the backplate 210 and a faceplate 712. The faceplate 712 includes a combination of features of the faceplates 302 and 402 shown in FIGS. 3 and 4.

The faceplate 712 is generally C-shaped and is also cylindrical. Specifically, the faceplate 712 comprises a cylindrical base portion 720 and a sidewall 722. The sidewall 722 extends from the cylindrical base portion 720. The sidewall 722 extends towards the backplate 210 and is attached to the backplate 210. Specifically, the sidewall 722 is attached to the OD of the backplate 210. The bottom surface 211 of the backplate 210 is perpendicular to an inner surface 723 of the sidewall 722.

The backplate 210 and the faceplate 712 define a plenum 730. Specifically, the bottom surface 211 of the backplate 210, a top surface 721 of the cylindrical base portion 720, and the inner surface 723 of the sidewall 722 define the plenum 730. The plenum 730 is in fluid communication with the inlet 206.

Both the top surface 721 of the cylindrical base portion 720, which faces away from a substrate, and a bottom surface 734 of the cylindrical base portion 720, which faces the substrate, are contoured instead of being flat. For example, the top surface 721 of the cylindrical base portion 720 is generally concave, and the bottom surface 734 of the cylindrical base portion 720 is generally convex.

Specifically, a first portion 750 of the top surface 721 extends radially inwardly from the ID of the side wall 722 for a first distance. The first portion 750 extends perpendicularly from the inner surface 723 of the sidewall 722 for the first distance. The first portion 750 extends parallel to the bottom surface 211 of the backplate 210 for the first distance. Thereafter, a second portion 752 of the top surface 721 extends radially inwards from the first portion 750 and tapers towards the bottom surface 734 of the cylindrical base portion 720 for a second distance. The second portion 752 tapers towards a center of the cylindrical base portion 720 for the second distance. Thereafter, a third portion 754 of the top surface 721 extends from the second portion 752 to the center of the cylindrical base portion 720 for a third distance. The third portion 754 extends parallel to the bottom surface 211 of the backplate 210 for the third distance. The bottom surface 211 of the backplate 210 is perpendicular to the inner surface 723 of the sidewall 722. Therefore, the third portion 754 of the top surface 721 also extends perpendicularly to the inner surface 723 of the sidewall 722 for the third distance.

The generally concave shaping of the top surface 721 described above is also called an internal contouring of the faceplate 712 because the top surface 721 of the cylindrical base portion 720 is also an inner surface of the faceplate 712. Note that the contouring of the top surface 721 may begin at any radial point on the top surface 721 of the cylindrical base portion 720. Similarly, the contouring of the top surface 721 may also end at any radial point on the top surface 721 of the cylindrical base portion 720. For example, the first, second, and third distances for the top surface 721 can be varied. Further, the slope of the contoured portion of the top surface 721 may be linear or polynomial.

Further, a first portion 751 of the bottom surface 734 extends radially inwardly from the OD of the side wall 722 for the first distance. The first portion 751 extends perpendicularly from the side wall 722 for the first distance. The first portion 751 extends parallel to the bottom surface 211 of the backplate 210 for the first distance. Thereafter, a second portion 753 of the bottom surface 734 extends radially inwardly from the first portion 751 for the second distance. The second portion 753 tapers away relative to the top surface 721 towards the center of the cylindrical base portion 720 for the second distance.

Thereafter, a third portion 755 of the bottom surface 734 extends from the second portion 753 to the center of the cylindrical base portion 720 for the third distance. The third portion 755 extends parallel to the bottom surface 211 of the backplate 210 for the third distance. The bottom surface 211 of the backplate 210 is perpendicular to the inner surface 723 of the sidewall 722. Therefore, the third portion 755 of the bottom surface 734 also extends perpendicularly to the inner surface 723 of the sidewall 722 for the third distance.

The generally convex shaping of the bottom surface 734 described above is also called an external contouring of the faceplate 712 because the bottom surface 734 of the cylindrical base portion 720 is also an outer surface of the faceplate 712. Note that the contouring of the bottom surface 734 may begin at any radial point on the bottom surface 734 of the cylindrical base portion 720. Similarly, the contouring of the bottom surface 734 may also end at any radial point on the bottom surface 734 of the cylindrical base portion 720. For example, the first, second, and third distances for the bottom surface 734 can be varied. Further, the slope of the contoured portion of the bottom surface 734 may be linear or polynomial.

While the contouring of the top surface 721 and the bottom surface 734 of the cylindrical base portion 720 is shown to be symmetrical, the contouring of the top surface 721 and the bottom surface 734 can be asymmetrical. For example, in some applications, the first, second, and third distances for the top surface 721 and the bottom surface 734 can be varied differently.

The cylindrical base portion 720 comprises a plurality of through holes 732-1, 732-2, 732-3, . . . , and 732-N (collectively the through holes 732). The through holes 732 extend from the bottom of the faceplate 712 to the top of the faceplate 712. Specifically, the through holes 732 extend from the bottom of the cylindrical base portion 720 to the top of the cylindrical base portion 720. More specifically, the through holes 732 extend from the bottom surface 734 of the cylindrical base portion 720, which faces the substrate, to the top surface 721 of the cylindrical base portion 720, which faces away from the substrate. The bottom surface 734 may also be called an outer surface 734 of the cylindrical base portion 720, and the top surface 721 may also be called an inner surface 721 of the cylindrical base portion 720.

The through holes 732 extend through the cylindrical base portion 720 vertically along an axis perpendicular to a plane in which the cylindrical base portion 720 and the backplate 210 lie. The through holes 732 are distributed from the center of the cylindrical base portion 720 up to the ID of the sidewall 722. The through holes 732 are in fluid communication with the plenum 730 and the inlet 206. The gases received from the inlet 206 flow through the plenum 730 and via the through holes 732 into the processing chamber.

Due to the contouring of the top surface 721 and the bottom surface 734 of the cylindrical base portion 720, the height (or depth) of the through holes 732 in the cylindrical base portion 720 can vary from the ID of the sidewall 722 to the center of the cylindrical base portion 720. For example, while the distances by which the portions of the top surface 721 and the bottom surface 734 extend are shown to be identical, the distances can be different. Therefore, while the height of the through holes 732 appears to be the same in the example shown, the height of the through holes 732 can differ in different zones (described below). The varying height of the through holes 732 changes the resistance to the flow of process gases across the radius of the showerhead 700. The changes in the resistance to the flow of process gases across the radius changes the film profile of the film deposited on the substrate.

Additionally, due to the contouring of the bottom surface 734 of the cylindrical base portion 720, the direction in which the process gases exit the through holes 732 also varies, which further changes the film profile of the film deposited on the substrate. Further, the gap between the showerhead 700 and the substrate can be varied as explained above with reference to FIG. 1. Changing the gap changes the plasma density the showerhead 700 and the substrate, which further changes the film profile of the film deposited on the substrate.

Specifically, due to the contouring of the top surface 721 and the bottom surface 734 of the cylindrical base portion 720, the cylindrical base portion 720 is divided into multiple concentric radial zones. In the example shown, the cylindrical base portion 720 is divided into first, second, and third concentric radial zones shown as Z1, Z2, and Z3, respectively. The first zone Z1 of the cylindrical base portion 720 extends radially inwards from the ID of the sidewall 722 towards the center of the cylindrical base portion 720 for the first distance. An OD of the first zone Z1 is the same as the ID of the sidewall 722. The second zone Z2 of the cylindrical base portion 720 extends radially inwards from an ID of the first zone Z1 towards the center of the cylindrical base portion 720 for the second distance. An OD of the second zone Z2 is the same as the ID of the first zone Z1. The third zone Z3 of the cylindrical base portion 720 extends radially inwards from an ID of the second zone Z2 to the center of the cylindrical base portion 720 for the third distance. An OD of the third zone Z3 is the same as the ID of the second zone Z2.

A width of the first zone Z1 (i.e., a difference between the OD and ID of the first zone Z1) is equal to the first distance. A width of the second zone Z2 (i.e., a difference between the OD and ID of the second zone Z2) is equal to the second distance. A width of the third zone Z3 (i.e., a distance between the OD of the third zone Z3 and the center of the cylindrical base portion 720) is equal to the third distance. The height of the through holes 732 in the first, second, and third radial zones shown as Z1, Z2, and Z3 of the cylindrical base portion 720 can vary depending on the contouring of the top surface 721 and the bottom surface 734 of the cylindrical base portion 720. Further, due to the contouring of the bottom surface 734 of the cylindrical base portion 720, the process gases exit through holes 732 in the second zone Z2 in a different direction compared to the through holes 732 in the first and third zones Z1 and Z3. Furthermore, the distances between the through holes 732 in the different zones and the substrate are also different. Accordingly, the film profile of a substate processed using the showerhead 700 is different than the film profiles of substates processed using the showerheads shown in FIGS. 2-6.

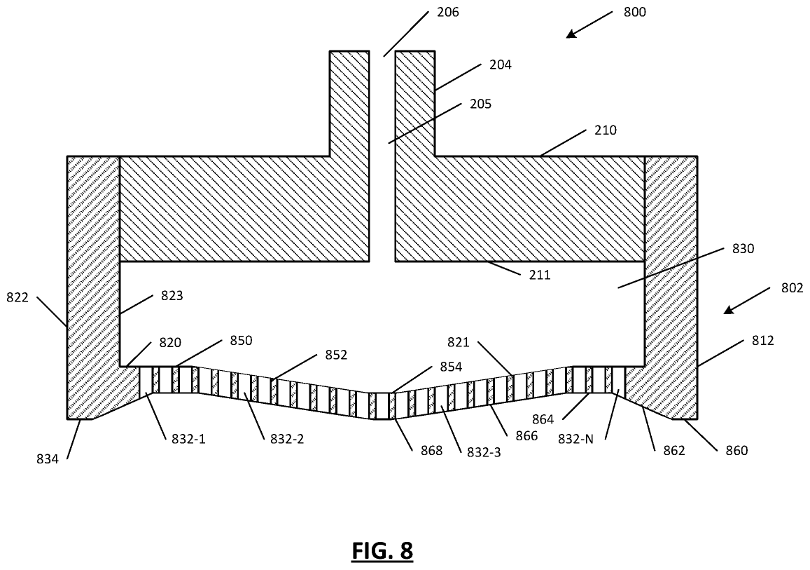

FIG. 8 shows a showerhead 800 comprising a faceplate according to the present disclosure. The faceplate comprises both internal and external contouring as described below in detail. The showerhead 800 comprises a base portion 802 and the stem portion 204. The base portion 802 comprises the backplate 210 and a faceplate 812. The faceplate 812 includes a combination of features of the faceplates 302 and 502 shown in FIGS. 3 and 5.

The faceplate 812 is generally C-shaped and is also cylindrical. Specifically, the faceplate 812 comprises a cylindrical base portion 820 and a sidewall 822. The sidewall 822 extends from the cylindrical base portion 820. The sidewall 822 extends towards the backplate 210 and is attached to the backplate 210. Specifically, the sidewall 822 is attached to the OD of the backplate 210. The bottom surface 211 of the backplate 210 is perpendicular to an inner surface 823 of the sidewall 822. The bottom surface 211 of the backplate 210 is perpendicular to an inner surface 823 of the sidewall 822.

The backplate 210 and the faceplate 812 define a plenum 830. Specifically, the bottom surface 211 of the backplate 210, a top surface 821 of the cylindrical base portion 820, and the inner surface 823 of the sidewall 822 define the plenum 830. The plenum 830 is in fluid communication with the inlet 206.

Both the top surface 821 of the cylindrical base portion 820, which faces away from a substrate, and a bottom surface 834 of the cylindrical base portion 820, which faces the substrate, are contoured instead of being flat. For example, the top surface 821 of the cylindrical base portion 820 is generally concave, and the bottom surface 834 of the cylindrical base portion 820 is generally convex.

Specifically, a first portion 850 of the top surface 821 extends radially inwardly from the ID of the side wall 822 for a first distance. The first portion 850 extends perpendicularly from the inner surface 823 of the sidewall 822 for the first distance. The first portion 850 extends parallel to the bottom surface 211 of the backplate 210 for the first distance. Thereafter, a second portion 852 of the top surface 821 extends radially inwards from the first portion 850 and tapers towards the bottom surface 834 of the cylindrical base portion 820 for a second distance. The second portion 852 tapers towards a center of the cylindrical base portion 820 for the second distance. Thereafter, a third portion 854 of the top surface 821 extends from the second portion 852 to the center of the cylindrical base portion 820 for a third distance. The third portion 854 extends parallel to the bottom surface 211 of the backplate 210 for the third distance. The bottom surface 211 of the backplate 210 is perpendicular to the inner surface 823 of the sidewall 822. The third portion 854 of the top surface 821 also extends perpendicularly to the inner surface 823 of the sidewall 822 for the third distance.

The generally concave shaping of the top surface 821 described above is also called an internal contouring of the faceplate 812 because the top surface 821 of the cylindrical base portion 820 is also an inner surface of the faceplate 812. Note that the contouring of the top surface 821 may begin at any radial point on the top surface 821 of the cylindrical base portion 820. Similarly, the contouring of the top surface 821 may also end at any radial point on the top surface 821 of the cylindrical base portion 820. For example, the first, second, and third distances for the top surface 821 can be varied. Further, the slope of the contoured portion of the top surface 821 may be linear or polynomial.

Further, a first portion 860 of the bottom surface 834 extends radially inwardly from the OD of the side wall 822 for a first distance. The first portion 860 extends perpendicularly from the side wall 822 for the first distance and is parallel to the bottom surface 211 of the backplate 210. Thereafter, a second portion 862 of the bottom surface 834 extends from the first portion 860 for a second distance. The second portion 860 tapers radially inwardly towards the top surface 821 for the second distance. The second portion 862 tapers towards a center of the cylindrical base portion 820 for the second distance.

Thereafter, a third portion 864 of the bottom surface 834 extends from the second portion 862 for a third distance. The third portion 864 extends radially inwardly towards the center of the cylindrical base portion 820 for the third distance. The third portion 864 extends perpendicularly to the side wall 822 for the third distance and is parallel to the bottom surface 211 of the backplate 210. The third portion 864 is also parallel to the first portion 860. Note that the first, second, and third distances for the bottom surface 834 of the cylindrical base portion 820 are different than the first, second, and third distances for the top surface 821 of the cylindrical base portion 820.

Thereafter, a fourth portion 866 of the bottom surface 834 extends from the third portion 864 for a fourth distance. The fourth portion 866 tapers away relative to the top surface 821 towards the center of the cylindrical base portion 820 for a fourth distance. Thereafter, a fifth portion 868 of the bottom surface 834 extends from the fourth portion 866 for a fifth distance. The fifth portion 868 extends from the fourth portion 866 to the center of the cylindrical base portion 820 for the fifth distance. The fifth portion 868 extends parallel to the bottom surface 211 of the backplate 210. The fifth portion 868 extends perpendicularly to the inner surface 823 of the sidewall 822 for the fifth distance. The fifth portion 868 is also parallel to the third portion 864 and the first portion 860.

The generally convex shaping of the bottom surface 834 described above is also called an external contouring of the faceplate 812 because the bottom surface 834 of the cylindrical base portion 820 is also an outer surface of the faceplate 812. Note that the contouring of the bottom surface 834 may begin at any radial point on the bottom surface 834 of the cylindrical base portion 820. Similarly, the contouring of the bottom surface 834 may also end at any radial point on the bottom surface 834 of the cylindrical base portion 820. For example, in some applications, the first, second, third, fourth, and fifth distances for the bottom surface 834 can be varied differently. Further, the slope of the contoured portion of the bottom surface 834 may be linear or polynomial.

While the contouring of portions of the top surface 821 and the bottom surface 834 of the cylindrical base portion 820 is shown to be symmetrical, the contouring of these portions of the top surface 821 and the bottom surface 834 can be asymmetrical. For example, in some applications, the second and third distances for the top surface 821 and the fourth and fifth distances for the bottom surface 834 can be varied differently.

The cylindrical base portion 820 comprises a plurality of through holes 832-1, 832-2, 832-3, . . . , and 832-N (collectively the through holes 832). The through holes 832 extend from the bottom of the faceplate 812 to the top of the faceplate 812. Specifically, the through holes 832 extend from the bottom of the cylindrical base portion 820 to the top of the cylindrical base portion 820. More specifically, the through holes 832 extend from the bottom surface 834 of the cylindrical base portion 820, which faces the substrate, to the top surface 821 of the cylindrical base portion 820, which faces away from the substrate. The bottom surface 834 may also be called an outer surface 834 of the cylindrical base portion 820, and the top surface 821 may also be called an inner surface 821 of the cylindrical base portion 820.

The through holes 832 extend through the cylindrical base portion 820 vertically along an axis perpendicular to a plane in which the cylindrical base portion 820 and the backplate 210 lie. The through holes 832 are distributed from the center of the cylindrical base portion 820 up to the ID of the sidewall 822. The through holes 832 are in fluid communication with the plenum 830 and the inlet 206. The gases received from the inlet 206 flow through the plenum 830 and via the through holes 832 into the processing chamber.

Due to the contouring of the top surface 821 and the bottom surface 834 of the cylindrical base portion 820, the height (or depth) of the through holes 832 in the cylindrical base portion 820 can vary from the ID of the sidewall 822 to the center of the cylindrical base portion 820. For example, while portions of the contouring of the top surface 821 and the bottom surface 834 are shown be similar, the contouring of these portions of the top surface 821 and the bottom surface 834 can be different. Therefore, while the height of some of the through holes 832 appears to be the same in the example shown, the height of the through holes 832 can differ in different zones, which are similar to those described above with reference to FIGS. 3 and 5.

Further, in the example shown, the height of the through holes 832 in the outermost zone proximate to the ID of the sidewall 822 is greater than the height of the rest of through holes 832. An example of the outermost zone is shown as the second zone Z2 shown in FIG. 5. Furthermore, due to the contouring of the bottom surface 834 of the cylindrical base portion 820, the through holes 832 in the outermost zone have varying height and therefore offer varying resistance to the flow of process gases. Specifically, the height of the through holes 832 in the outermost zone gradually decreases from the ID of the sidewall 822 towards the center of the cylindrical base portion 820. Therefore, the through holes 832 in the outermost zone offer a gradually decreasing resistance to the flow of process gases from the ID of the sidewall 822 towards the center of the cylindrical base portion 820.

Accordingly, the varying height of the through holes 832 changes the resistance to the flow of process gases across the radius of the showerhead 800. The changes in the resistance to the flow of process gases across the radius changes the film profile of the film deposited on the substrate. Additionally, due to the contouring of the bottom surface 834 of the cylindrical base portion 820, the direction in which the process gases exit the through holes 832 also varies, which further changes the film profile of the film deposited on the substrate. Further, the distances between the through holes 832 in the different zones and the substrate are also different. Furthermore, the gap between the showerhead 800 and the substrate can be varied as explained above with reference to FIG. 1. Changing the gap changes the plasma density the showerhead 800 and the substrate, which further changes the film profile of the film deposited on the substrate. Accordingly, the film profile of a substate processed using the showerhead 800 is different than the film profiles of substates processed using the showerheads shown in FIGS. 2-7.

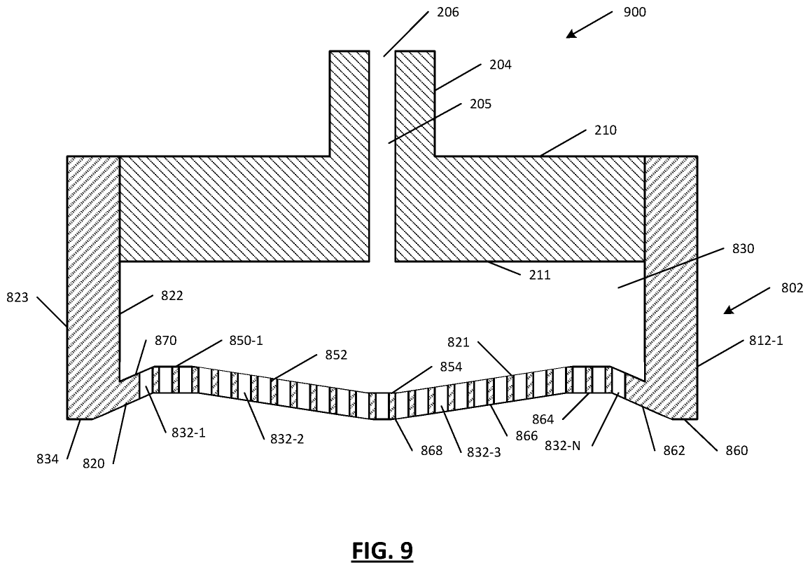

FIG. 9 shows a showerhead 900, which is a variation of the showerhead 800 shown in FIG. 8. The showerhead 900 comprises a faceplate 812-1 according to the present disclosure. The showerhead 900 is similar to the showerhead 800 except for the following difference in the faceplate 812-1. In the showerhead 800, the first portion 850 of the top surface 821 of the cylindrical base portion 820 extends parallel to the bottom surface 211 of the backplate 210 for the first distance as described above with reference to FIG. 8. Instead, in the showerhead 900, an outermost portion of the top surface 821 is tapered as shown at 870 in FIG. 9. Accordingly, the first portion 850 shown in FIG. 8 is shown as a first portion 850-1 in FIG. 9.

Specifically, the outermost portion 870 of the top surface 821 extends radially inwardly from the ID of the side wall 822 for a fourth distance. The outermost portion 870 extends towards the bottom surface 211 of the backplate 210 for the fourth distance. Thereafter, the first portion 850-1 extends radially inwardly from the outermost portion 870 for less than the first distance described with reference to the first portion 850 shown in FIG. 8. The first portion 850-1 extends perpendicularly to the inner surface 823 of the sidewall 822 and parallel to the bottom surface 211 of the backplate 210 for less than the first distance. The remainder of the showerhead 900 is similar to the remainder of the showerhead 800.

Due to the tapered outermost portion 870, the outermost through holes 832 (e.g., in the second zone Z2 shown in FIG. 5) have varying height and offer varying resistance to the flow of process gases. Additionally, due to the tapering of the outermost portion 870, the direction in which the process gases exit the outermost through holes 832 also varies, which further changes the film profile of the film deposited on the substrate compared to the showerhead 800. Further, the distances between the outermost through holes 832 and the substrate are also different. Accordingly, the film profile of a substate processed using the showerhead 900 is different than the film profiles of substates processed using the showerhead 800 and also other showerheads shown in FIGS. 2-7.

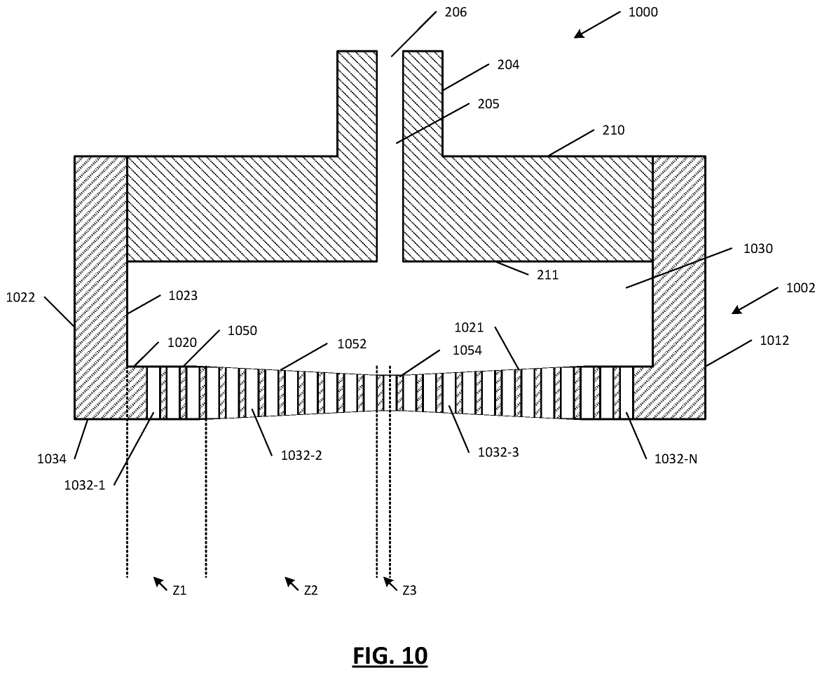

FIG. 10 shows a showerhead 1000 comprising a faceplate according to the present disclosure. The faceplate comprises both internal and external contouring as described below in detail. The showerhead 1000 comprises a base portion 1002 and the stem portion 204. The base portion 1002 comprises the backplate 210 and a faceplate 1012. The faceplate 1012 includes a combination of features of the faceplates 302 and 602 shown in FIGS. 3 and 6.

The faceplate 1012 is generally C-shaped and is also cylindrical. Specifically, the faceplate 1012 comprises a cylindrical base portion 1020 and a sidewall 1022. The sidewall 1022 extends from the cylindrical base portion 1020. The sidewall 1022 extends towards the backplate 210 and is attached to the backplate 210. Specifically, the sidewall 1022 is attached to the OD of the backplate 210. The bottom surface 211 of the backplate 210 is perpendicular to an inner surface 1023 of the sidewall 1022.

The backplate 210 and the faceplate 1012 define a plenum 1030. Specifically, the bottom surface 211 of the backplate 210, a top surface 1021 of the cylindrical base portion 1020, and the inner surface 1023 of the sidewall 1022 define the plenum 1030. The plenum 1030 is in fluid communication with the inlet 206.

Both the top surface 1021 of the cylindrical base portion 1020, which faces away from a substrate, and a bottom surface 1034 of the cylindrical base portion 1020, which faces the substrate, are contoured instead of being flat. For example, the top surface 1021 of the cylindrical base portion 1020 is generally concave, and the bottom surface 1034 of the cylindrical base portion 1020 is also generally concave. In the example shown, the contouring of the top surface 1021 and bottom surface 1034 of the cylindrical base portion 1020 is such that the top surface 1021 and bottom surface 1034 of the cylindrical base portion 1020 are mirror images of each other. However, in some applications, the contouring of the top surface 1021 and bottom surface 1034 of the cylindrical base portion 1020 can be different.

As shown, a first portion 1050 of the top surface 1021 extends radially inwardly from the ID of the side wall 1022 for a first distance. The first portion 1050 extends perpendicularly from the inner surface 1023 of the sidewall 1022 for the first distance. The first portion 1050 extends parallel to the bottom surface 211 of the backplate 210 for the first distance. Thereafter, a second portion 1052 of the top surface 1021 extends radially inwards from the first portion 1050 and tapers towards the bottom surface 1034 of the cylindrical base portion 1020 for a second distance. The second portion 1052 tapers towards a center of the cylindrical base portion 1020 for the second distance. Thereafter, a third portion 1054 of the top surface 1021 extends from the second portion 1052 to the center of the cylindrical base portion 1020 for a third distance. The third portion 1054 extends parallel to the bottom surface 211 of the backplate 210 for the third distance. The bottom surface 211 of the backplate 210 is perpendicular to the inner surface 1023 of the sidewall 1022. Therefore, the third portion 1054 of the top surface 1021 also extends perpendicularly to the inner surface 1023 of the sidewall 1022 for the third distance.

The generally concave shaping of the top surface 1021 described above is also called an internal contouring of the faceplate 1012 because the top surface 1021 of the cylindrical base portion 1020 is also an inner surface of the faceplate 1012. Note that the contouring of the top surface 1021 may begin at any radial point on the top surface 1021 of the cylindrical base portion 1020. Similarly, the contouring of the top surface 1021 may also end at any radial point on the top surface 1021 of the cylindrical base portion 1020. For example, the first, second, and third distances for the top surface 1021 can be varied. Further, the slope of the contoured portion of the top surface 1021 may be linear or polynomial.

Further, a first portion 1051 of the bottom surface 1034 extends radially inwardly from the OD of the side wall 1022 for the first distance. The first portion 1051 extends perpendicularly from the side wall 1022 for the first distance. The first portion 1051 extends parallel to the bottom surface 211 of the backplate 210 for the first distance. The first portion 1051 of the top surface 1021 is parallel to the first portion 1050 of the bottom surface 1034. Thereafter, a second portion 1053 of the bottom surface 1034 extends radially inwardly from the first portion 1051 for the second distance. The second portion 1053 tapers towards the top surface 1021 of the cylindrical base portion 1020 for the second distance. The second portion 1053 tapers towards a center of the cylindrical base portion 1020 for the second distance.

Thereafter, a third portion 1055 of the bottom surface 1034 extends from the second portion 1053 to the center of the cylindrical base portion 1020 for the third distance. The third portion 1055 extends parallel to the bottom surface 211 of the backplate 210. The bottom surface 211 of the backplate 210 is perpendicular to the inner surface 1023 of the sidewall 1022. Therefore, the third portion 1055 of the bottom surface 1034 also extends perpendicularly to the inner surface 1023 of the sidewall 1022 for the third distance. The third portion 1054 of the top surface 1021 is parallel to the third portion 1055 of the bottom surface 1034.

The generally concave shaping of the bottom surface 1034 described above is also called an external contouring of the faceplate 1012 because the bottom surface 1034 of the cylindrical base portion 1020 is also an outer surface of the faceplate 1012. Note that the contouring of the bottom surface 1034 may begin at any radial point on the bottom surface 1034 of the cylindrical base portion 1020. Similarly, the contouring of the bottom surface 1034 may also end at any radial point on the bottom surface 1034 of the cylindrical base portion 1020. For example, the first, second, and third distances for the bottom surface 1034 can be varied. Further, the slope of the contoured portion of the bottom surface 1034 may be linear or polynomial.

In the example shown, the first, second, and third distances for the top surface 1021 and the bottom surface 1034 are shown to be equal. However, in some applications, the first, second, and third distances for the top surface 1021 may be different than the first, second, and third distances for the bottom surface 1034. Accordingly, while the contouring of the top surface 1021 and the bottom surface 1034 is shown to be symmetric, the contouring of the top surface 1021 and the bottom surface 1034 can be asymmetric.

The cylindrical base portion 1020 comprises a plurality of through holes 1032-1, 1032-2, 1032-3, . . . , and 1032-N (collectively the through holes 1032). The through holes 1032 extend from the bottom of the faceplate 1012 to the top of the faceplate 1012. Specifically, the through holes 1032 extend from the bottom of the cylindrical base portion 1020 to the top of the cylindrical base portion 1020. More specifically, the through holes 1032 extend from the bottom surface 1034 of the cylindrical base portion 1020, which faces the substrate, to the top surface 1021 of the cylindrical base portion 1020, which faces away from the substrate. The bottom surface 1034 may also be called an outer surface 1034 of the cylindrical base portion 1020, and the top surface 1021 may also be called an inner surface 1021 of the cylindrical base portion 1020.

The through holes 1032 extend through the cylindrical base portion 1020 vertically along an axis perpendicular to a plane in which the cylindrical base portion 1020 and the backplate 210 lie. The through holes 1032 are distributed from the center of the cylindrical base portion 1020 up to the ID of the sidewall 1022. The through holes 1032 are in fluid communication with the plenum 1030 and the inlet 206. The gases received from the inlet 206 flow through the plenum 1030 and via the through holes 1032 into the processing chamber.

Due to the contouring of the top surface 1021 and the bottom surface 1034 of the cylindrical base portion 1020, the height (or depth) of the through holes 1032 in the cylindrical base portion 1020 can vary from the ID of the sidewall 1022 to the center of the cylindrical base portion 1020. The varying height of the through holes 1032 changes the resistance to the flow of process gases across the radius of the showerhead 1000. The changes in the resistance to the flow of process gases across the radius changes the film profile of the film deposited on the substrate.

Additionally, due to the contouring of the bottom surface 1034 of the cylindrical base portion 1020, the direction in which the process gases exit the through holes 1032 also varies, which further changes the film profile of the film deposited on the substrate. Further, the gap between the showerhead 1000 and the substrate can be varied as explained above with reference to FIG. 1. Changing the gap changes the plasma density the showerhead 1000 and the substrate, which further changes the film profile of the film deposited on the substrate.

Specifically, due to the contouring of the top surface 1021 and the bottom surface 1034 of the cylindrical base portion 1020, the cylindrical base portion 1020 is divided into multiple concentric radial zones. In the example shown, the cylindrical base portion 1020 is divided into first, second, and third concentric radial zones shown as Z1, Z2, and Z3, respectively. The first zone Z1 of the cylindrical base portion 1020 extends radially inwards from the ID of the sidewall 1022 towards the center of the cylindrical base portion 1020 for the first distance. An OD of the first zone Z1 is the same as the ID of the sidewall 1022. The second zone Z2 of the cylindrical base portion 1020 extends radially inwards from an ID of the first zone Z1 towards the center of the cylindrical base portion 1020 for the second distance. An OD of the second zone Z2 is the same as the ID of the first zone Z1. The third zone Z3 of the cylindrical base portion 1020 extends radially inwards from an ID of the second zone Z2 to the center of the cylindrical base portion 1020 for the third distance. An OD of the third zone Z3 is the same as the ID of the second zone Z2.

A width of the first zone Z1 (i.e., a difference between the OD and ID of the first zone Z1) is equal to the first distance. A width of the second zone Z2 (i.e., a difference between the OD and ID of the second zone Z2) is equal to the second distance. A width of the third zone Z3 (i.e., a distance between the OD of the third zone Z3 and the center of the cylindrical base portion 1020) is equal to the third distance. The height of the through holes 1032 in the first, second, and third radial zones shown as Z1, Z2, and Z3 of the cylindrical base portion 1020 can vary depending on the contouring of the top surface 1021 and the bottom surface 1034 of the cylindrical base portion 1020.

For example, the height of the outermost through holes 1032 in the first zone Z1 is greater than the through holes 1032 in the second and third zones Z2 and Z3. Therefore, the through holes 1032 in the first zone Z1 offer greater resistance for the flow of process gases than the through holes 1032 in the second and third zones Z2 and Z3. The height of the innermost through holes 1032 in the third zone Z3 is less than the through holes 1032 in the first and second zones Z1 and Z2. Therefore, the through holes 1032 in the third zone Z3 offer less resistance for the flow of process gases than the through holes 1032 in the first and second zones Z1 and Z2.

Further, the height of the through holes 1032 in the second zone Z2 decreases from the OD of the second zone Z2 to the ID of the second zone Z2 (i.e., towards the center of the cylindrical base portion 1034). Therefore, the through holes 1032 in the second zone Z2 offer a gradually decreasing resistance to the flow of process gases from the OD of the second zone Z2 to the ID of the second zone Z2 (i.e., towards the center of the cylindrical base portion 1034).

Additionally, due to the contouring of the bottom surface 1034 of the cylindrical base portion 1020, the process gases exit through holes 1032 in the second zone Z2 in a different direction compared to the through holes 1032 in the first and third zones Z1 and Z3. Furthermore, the distances between the through holes 1032 in the different zones and the substrate are also different. Accordingly, the film profile of a substate processed using the showerhead 1000 is different than the film profiles of substates processed using the showerheads shown in FIGS. 2-9.

Note that while convex internal contouring of faceplates is not explicitly shown, in the showerhead 200, the top surface 221 of the cylindrical base portion 234 of the faceplate 212 can be contoured to have a convex shape. For example, the top surface 221 of the cylindrical base portion 234 of the faceplate 212 can be curved towards the bottom surface 211 of the backplate 210. In this configuration, the properties of the through holes and of flow of the process gases via the through holes described above with reference to FIG. 3 will be reversed or inverted. Further, similar convex contouring of the top surfaces of the cylindrical base portions can be implemented together with the contouring of the bottom surfaces of the cylindrical base portions shown in the showerheads shown in FIGS. 4-10 to achieve additional film profiles and properties.

The foregoing description is merely illustrative in nature and is not intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g., a server) can provide process recipes to a system over a network, which may include a local network or the Internet. The remote computer may include a user interface that enables entry or programming of parameters and/or settings, which are then communicated to the system from the remote computer.

In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

1. A showerhead for processing a substrate, the showerhead comprising:
a backplate; and
a faceplate attached to the backplate, wherein the faceplate comprises:
a first surface facing the backplate;
a second surface opposite to the first surface; and
a plurality of through holes extending between the first and second surfaces,
wherein a center portion of the second surface of the faceplate is convex.

2-17. (canceled)

18. The showerhead of claim 1 wherein the backplate and the faceplate are cylindrical; the faceplate comprises a sidewall attached to the backplate; the backplate, the faceplate, and the sidewall define a plenum; the showerhead further comprising:
a stem portion attached to the backplate, wherein the stem portion comprises a gas inlet; and
a conduit extending from the gas inlet through the stem portion, the backplate, and the faceplate to the plenum, wherein with the gas inlet, the plenum, and the through holes are in fluid communication with each other.

19. A system comprising:
the showerhead of claim 1;
a pedestal to support the substrate;
an actuator to move the pedestal relative to the showerhead; and
a controller to control the actuator.

20. A system comprising:
the showerhead of claim 18;
a gas source to supply a gas to the gas inlet;
a pedestal to support the substrate;
a radio frequency source to supply radio frequency power to activate the gas;
an actuator to move the pedestal relative to the showerhead; and
a controller to control the gas source, the radio frequency source, and the actuator.

21. The showerhead of claim 1 wherein the backplate and the faceplate are cylindrical and wherein a remainder of the second surface of the faceplate extends radially outwards from ends of the center portion of the faceplate and is flat.

22. The showerhead of claim 21 wherein the first surface of the faceplate facing the backplate is flat and is parallel to the remainder.

23. The showerhead of claim 21 wherein the center portion and a portion of the remainder comprise the plurality of through holes.

24. The showerhead of claim 1 wherein the first surface of the faceplate facing the backplate is flat.

25. The showerhead of claim 1 wherein:
the backplate and the faceplate are cylindrical;
a first remainder of the second surface of the faceplate extends radially outwards from ends of the center portion and is flat; and
a second remainder of the second surface of the faceplate extends radially outwards from ends of the first remainder and extends radially outwards and downwards.

26. The showerhead of claim 25 wherein the first surface of the faceplate facing the backplate is flat and is parallel to the first remainder.

27. The showerhead of claim 25 wherein the center portion, the first remainder, and a portion of the second remainder comprise the plurality of through holes.

28. The showerhead of claim 1 wherein a center portion of the first surface of the faceplate is concave.

29. The showerhead of claim 28 wherein the center portion of the first surface of the faceplate is parallel to the center portion of the second surface of the faceplate.

30. The showerhead of claim 28 wherein:
the backplate and the faceplate are cylindrical;
a first remainder of the first surface of the faceplate extends radially outwards from ends of the center portion of the first surface and is flat;
a second remainder of the second surface of the faceplate extends radially outwards from ends of the center portion of the second surface and is flat; and
the first remainder is parallel to the second remainder.

31. The showerhead of claim 30 wherein the center portions of the first and second surfaces and portions of the first and second remainders comprise the plurality of through holes.

32. The showerhead of claim 28 wherein:
the backplate and the faceplate are cylindrical;
a remainder of the first surface of the faceplate extends radially outwards from ends of the center portion of the first surface and is flat;
a first remainder of the second surface of the faceplate extends radially outwards from ends of the center portion of the second surface and is flat;
a second remainder of the second surface of the faceplate extends radially outwards from ends of the first remainder and extends radially outwards and downwards; and
the remainder of the first surface of the faceplate is parallel to the first remainder of the second surface of the faceplate.

33. The showerhead of claim 32 wherein the center portions of the first and second surfaces, a portion of the remainder of the first surface, and portions of the first and second remainders of the second surface comprise the plurality of through holes.

34. The showerhead of claim 28 wherein:
the backplate and the faceplate are cylindrical;
a first remainder of the first surface of the faceplate extends radially outwards from ends of the center portion of the first surface and is flat;
a second remainder of the first surface of the faceplate extends radially outwards from ends of the first remainder and extends radially outwards and downwards;
a third remainder of the second surface of the faceplate extends radially outwards from ends of the center portion of the second surface and is flat; and
a fourth remainder of the second surface of the faceplate extends radially outwards from ends of the third remainder and extends radially outwards and downwards.

35. The showerhead of claim 34 wherein:
the first remainder of the first surface of the faceplate is parallel to the third remainder of the second surface of the faceplate; and
the second remainder of the first surface of the faceplate is parallel to the fourth remainder of the second surface of the faceplate.

36. The showerhead of claim 34 wherein the center portions of the first and second surfaces and portions of the first through fourth remainders of the first and second surfaces comprise the plurality of through holes.

37. A showerhead for processing a substrate, the showerhead comprising:
a backplate; and
a faceplate attached to the backplate, wherein the backplate and the faceplate are cylindrical, and wherein the faceplate comprises:
a first surface facing the backplate;
a second surface opposite to the first surface; and
a plurality of through holes extending between the first and second surfaces,
wherein a center portion of the second surface is concave, and
wherein a remainder of the second surface of the faceplate extends radially outwards from ends of the center portion of the faceplate and is flat.

38. The showerhead of claim 37 wherein the center portion and a portion of the remainder comprise the plurality of through holes.

39. The showerhead of claim 37 wherein the first surface of the faceplate facing the backplate is flat.

40. The showerhead of claim 37 wherein the first surface of the faceplate facing the backplate is flat and is parallel to the remainder.

41. The showerhead of claim 37 wherein:
wherein a center portion of the first surface of the faceplate is concave; and
wherein a remainder of the first surface extends radially outwards from ends of the center portion of the first surface and is flat.

42. The showerhead of claim 41 wherein the first surface of the faceplate is a mirror image of the second surface of the faceplate.

43. The showerhead of claim 41 wherein the center portions of the first and second surfaces of the faceplate, a portion of the remainder of the second surface of the faceplate, and a portion of the remainder of the first surface of the faceplate comprise the plurality of through holes.

44. The showerhead of claim 43 wherein the portion of the remainder of the second surface is parallel to the portion of the remainder of the first surface.
